(19) United States
(12) Patent Application Publication
(10) Pub. No.: US 2024/0057369 A1
(43) Pub. Date: Feb. 15, 2024

(54) LIGHT-EMITTING ELEMENT

(71) Applicant: SHARP KABUSHIKI KAISHA, Sakai City, Osaka (JP)

(72) Inventor: YOSHIHIRO UETA, Sakai City, Osaka (JP)

(73) Assignee: SHARP KABUSHIKI KAISHA, Sakai City, Osaka (JP)

(21) Appl. No.: 18/271,683

(22) PCT Filed: Jan. 13, 2021
(86) PCT No.: PCT/JP2021/000800

§ 371 Date: Jul. 11, 2023

(51) Int. Cl. H10K 50/16; H10K 50/115

(52) U.S. Cl. CPC H10K 50/166; H10K 50/115; H10K 2102/351

(57) ABSTRACT

A light-emitting element includes: a cathode; an anode opposite the cathode; a light-emitting layer between the cathode and the anode; and an electron transport layer between the cathode and the light-emitting layer, the electron transport layer containing either a compound containing a Group IIB element, a Group IVB element, and elemental nitrogen or a compound containing the Group IVB element, a Group VIB element, and elemental boron.

### TECHNICAL FIELD

The present disclosure relates to light-emitting elements.

### BACKGROUND ART

QLEDs (quantum-dot light-emitting diodes) and OLEDs (organic light-emitting diodes) have been attracting great attention as light-emitting elements that are applicable, for example, to display devices and lighting devices and in other various fields.

Conventional QLEDs and OLEDs are however still short of delivering satisfactory levels of luminous efficiency, and active research is being undertaken to improve luminous efficiency.

Patent Literature 1 describes a QLED including a light-emitting layer containing quantum dots of a core-shell structure, with the core being made of a metal nitride.

### CITATION LIST

### Patent Literature

Patent Literature 1: Japanese Unexamined Patent Application Publication, Tokukai, No. 2018-154666

### SUMMARY

### Technical Problem

In this QLED described in Patent Literature 1, however, the core material for the core-shell quantum dots in the light-emitting layer is made solely of a metal nitride. Therefore, the QLED has an issue that the balance between the holes and electrons injected to the light-emitting layer, in other words, the charge-carrier balance, cannot be improved to deliver satisfactory levels of luminous efficiency.

The present disclosure, in an aspect thereof, has been made in view of this issue and has an object to provide a light-emitting element with an improved charge-carrier balance, hence with enhanced luminous efficiency and reliability.

### Solution to Problem

A light-emitting element of the present disclosure, to address this issue, includes:
a cathode;
an anode opposite the cathode;
a light-emitting layer between the cathode and the anode; and
an electron transport layer between the cathode and the light-emitting layer, the electron transport layer containing either a compound containing a Group IIB (12) element, a Group IVB (14) element, and elemental nitrogen or a compound containing the Group IVB (14) element, a Group VIB (16) element, and elemental boron.

A light-emitting element of the present disclosure, to address the issue, includes:
a cathode;
an anode opposite the cathode;
a light-emitting layer containing quantum dots between the cathode and the anode; and
an electron transport layer in contact with the light-emitting layer between the cathode and the light-emitting layer, the electron transport layer being an n-type semiconductor having a conduction band minimum that differs from a vacuum energy level by a smaller absolute value than a conduction band minimum of the light-emitting layer differs from the vacuum energy level, wherein
the light-emitting layer includes:
   a first layer in contact with the electron transport layer; and
   a second layer in contact with the first layer and separated from the electron transport layer, and
only the second layer in the light-emitting layer emits light.

A light-emitting element of the present disclosure, to address the issue, includes: a cathode; an anode opposite the cathode; a light-emitting layer between the cathode and the anode; and an electron transport layer between the cathode and the light-emitting layer, wherein the electron transport layer has an ionization potential and an electron affinity that are both lower than an electron affinity of the light-emitting layer and also exhibits a band gap.

### Advantageous Effects

The present disclosure, in an aspect thereof, is capable of providing a light-emitting element with an improved charge-carrier balance, hence with enhanced luminous efficiency and reliability.

### BRIEF DESCRIPTION OF DRAWINGS

FIG. 1 is a schematic cross-sectional view of a structure of a light-emitting element in accordance with Embodiment 1.

FIG. 2 is a schematic band diagram for a light-emitting layer and an electron transport layer in the light-emitting element in accordance with Embodiment 1.

FIG. 3 is a schematic band diagram when the light-emitting layer and the electron transport layer in the light-emitting element in accordance with Embodiment 1 are joined.

FIG. 4 is a diagram illustrating an example of a material that can be used as an electron transport layer in the light-emitting element in accordance with Embodiment 1.

FIG. 5 is a diagram representing a relationship between the band gap and the wurtzite lattice constant of exemplary materials that can be used as an electron transport layer in the light-emitting element in accordance with Embodiment 1.

FIG. 6 is a schematic band diagram for an alternative electron transport layer in the light-emitting element in accordance with Embodiment 1.

FIG. 7 is a diagram illustrating properties of the light-emitting element in accordance with Embodiment 1.

FIG. 8 is a schematic cross-sectional view of a structure of a light-emitting element in accordance with Embodiment 2.

FIG. 9 is a schematic diagram representing a structure of a display device including a light-emitting element in accordance with Embodiment 3.

In FIG. 10, (a) is a schematic cross-sectional view of a structure of a light-emitting element in accordance with Embodiment 3 in a red subpixel in the display device shown in FIG. 9, (b) is a schematic cross-sectional view of a structure of a light-emitting element in accordance with Embodiment 3 in a green subpixel in the display device shown in FIG. 9, and (c) is a schematic cross-sectional view of a structure of a light-emitting element in accordance with Embodiment 3 in a blue subpixel in the display device shown in FIG. 9.

FIG. 11 is a schematic cross-sectional view of a structure of a light-emitting element in accordance with Embodiment 4.

FIG. 12 is a diagram illustrating an electron transport layer in the light-emitting element in accordance with Embodiment 4.

FIG. 13 is a diagram illustrating an electron transport layer in the light-emitting element in accordance with Embodiment 4.

In FIG. 14, (a) is a schematic cross-sectional view of a structure of a light-emitting element in accordance with Embodiment 4 in a red subpixel in the display device shown in FIG. 9, (b) is a schematic cross-sectional view of a structure of a light-emitting element in accordance with Embodiment 4 in a green subpixel in the display device shown in FIG. 9, and (c) is a schematic cross-sectional view of a structure of a light-emitting element in accordance with Embodiment 4 in a blue subpixel in the display device shown in FIG. 9.

FIG. 15 is a schematic cross-sectional view of a structure of a light-emitting element in accordance with Embodiment 5.

FIG. 16 is a schematic cross-sectional view of a structure of a light-emitting element in accordance with Embodiment 6.

In FIG. 17, (a), (b), and (c) are schematic band diagrams for a quantum-dot layer and a light-emitting layer when the quantum-dot layer has a conduction band minimum (CBM) that is lower than the LUMO of the light-emitting layer, (d), (e), and (f) are schematic band diagrams for the quantum-dot layer and the light-emitting layer when the quantum-dot layer has a conduction band minimum (CBM) that is higher than the LUMO of the light-emitting layer, and (g), (h), and (i) are schematic band diagrams for the quantum-dot layer and the light-emitting layer when the quantum-dot layer has a conduction band minimum (CBM) that is equal to the LUMO of the light-emitting layer.

FIG. 18 is a diagram illustrating problems in a hole transport layer when the carriers in a light-emitting element include excessive electrons.

In FIG. 19, (a) and (b) are diagrams illustrating problems caused by a shallow conduction band minimum of the electron transport layer when the carriers in a light-emitting element include excessive electrons.

FIG. 20 is a diagram representing a relationship between a voltage and a current density in an electron-only device for each of two types of ZnO with different conduction band minimums (CBMs) used as an electron transport layer.

FIG. 21 is a diagram representing a relationship between a voltage and a luminance in an electron-only device for each of two types of ZnO with different conduction band minimums (CBMs) used as an electron transport layer.

FIG. 22 is a diagram representing a relationship between a voltage and a current density in a hole-only device for each of NiO alone, a combination of NiO and an organic material, and an organic material alone used as a hole transport layer.

FIG. 23 is a diagram representing a relationship between a voltage and a luminance in a hole-only device for each of NiO alone, a combination of NiO and an organic material, and an organic material alone used as a hole transport layer.

In FIG. 24, (a), (b), and (c) are schematic band diagrams illustrating problems in a light-emitting element including a hole transport layer made solely of an organic material and an electron transport layer made of ZnO.

### DESCRIPTION OF EMBODIMENTS

First, referring to FIGS. 18 to 24, a description is given of reasons why it is impossible to address the excess electron condition of carriers without compromising on reliability if the light-emitting element includes ZnO as an electron transport layer and NiO alone, a combination of NiO and an organic material, or an organic material alone as a hole transport layer.

FIG. 18 is a diagram illustrating problems in a hole transport layer when the carriers in a light-emitting element include excessive electrons.

FIG. 18 represents results of a reliability test on light-emitting elements that include ZnO as an electron transport layer and that only differ in the structures of the hole transport layer and the hole injection layer. Note that these reliability test results were obtained under the following accelerated conditions. Acceleration was achieved by a light-flux load approximately 10 times the luminance expected when the light-emitting element is incorporated in a display device (panel) and, as to the drive current, by an electric current load approximately 2.5 times the typical TFT drive current and the electric power load approximately 6.25 times the typical TFT drive current. In addition, measurement was made at a temperature of 25° C. and a humidity of 60%.

In FIG. 18, polyethylenedioxythiophene (PEDOT):polystyrene sulfonate (PSS)/polyvinyl carbazole (PVK) is an example of the use of an organic material alone as a component of both a hole transport layer and a hole injection layer, where the light-emitting element includes a hole transport layer made of PVK (organic material) and a hole injection layer made of PEDOT:PSS (organic material). In FIG. 18, NiO/PVK is an example of the use of an organic material and an inorganic material as a component of a hole transport layer and a hole injection layer respectively, where the light-emitting element includes a hole transport layer made of PVK (organic material) and a hole injection layer made of NiO (inorganic material). In FIG. 18, NiO is an example of the use of an inorganic material alone as a component of both a hole transport layer and a hole injection layer, where the light-emitting element includes a hole transport layer and a hole injection layer both made of NiO (inorganic material).

Referring to FIG. 18, the luminance of the light-emitting element decreases over time first in PEDOT:PSS/PVK, followed by NiO/PVK, and then by NiO (i.e., the degradation rate is high in the order of PEDOT:PSS/PVK, NiO/PVK, and NiO). These results show that the reliability of the light-emitting element falls when the light-emitting element contains an organic material in a larger proportion as the hole transport layer and the hole injection layer, which is presumed to be caused by the following mechanism. An overflow occurs of electrons from the electron-excessive light-emitting layer to the hole transport layer and the hole injection layer, and when the organic material, which has lower chemical stability than the inorganic material, is used as the hole transport layer and the hole injection layer, the organic material that receives the excessive electrons decays more than the inorganic material.

In FIG. 19, (a) and (b) are diagrams illustrating problems caused by a shallow conduction band minimum of the electron transport layer when the carriers in a light-emitting element include excessive electrons.

Portion (a) of FIG. 19 is a schematic band diagram for quantum dots (QDs) in the light-emitting layer and for MgZnO and ZnO, which have different conduction band minimums (CBMs), in the electron transport layer.

As shown in (a) of FIG. 19, since MgZnO has a shallower conduction band minimum (CBM) than ZnO, the electron injection property of the light-emitting layer to quantum dots (QDs) improves, thereby aggravating the excess electron condition of the light-emitting layer, when MgZnO is used as the electron transport layer over when ZnO is used as the electron transport layer.

Portion (b) of FIG. 19 represents results of a reliability test on light-emitting elements that include NiO/PVK as both a hole transport layer and a hole injection layer and that only differ in the structure of the electron transport layer. The reliability test was conducted at a constant current density. Note that these reliability test results were obtained under the following accelerated conditions. Acceleration was achieved by a light-flux load approximately 10 times the luminance expected when the light-emitting element is incorporated in a display device (panel) and, as to the drive current, by an electric current load approximately 2.5 times the typical TFT drive current and the electric power load approximately 6.25 times the typical TFT drive current. In addition, measurement was made at a temperature of 25° C. and a humidity of 60%.

In (b) of FIG. 19, MgZnO is a case where MgZnO is used as the electron transport layer, and ZnO-1 to ZnO-3 are cases where ZnO is used as the electron transport layer. ZnO with different conduction band minimums (CBMs) was used in ZnO-1 and in ZnO-2 and ZnO-3.

Portion (b) of FIG. 19 shows that the light-emitting element including MgZnO as the electron transport layer exhibits an initial degradation rate and a long-term degradation rate that are both higher than the light-emitting element including ZnO as the electron transport layer. As described above, this is presumably because MgZnO has a shallower conduction band minimum (CBM) than ZnO, and the electron injection property of the light-emitting layer to quantum dots (QDs) improves when MgZnO is used as the electron transport layer over when ZnO is used as the electron transport layer.

FIG. 20 is a diagram representing a relationship between a voltage and a current density in an electron-only device passing electrons alone for each of two types of ZnO with different conduction band minimums (CBMs) used as an electron transport layer. Note that the vertical line in FIG. 20 indicates 3 V.

An electron-only device passing electrons alone is capable of only injecting electrons to the light-emitting layer with the injection of holes to the light-emitting layer being blocked and is suitably used in analyzing the injection of electrons to the light-emitting layer. Electric current is a flow of electric charges per time, and the injection of electrons to the light-emitting layer can be estimated from the current density in the electron-only device.

FIG. 21 is a diagram representing a relationship between a voltage and a luminance in an electron-only device passing electrons alone for each of two types of ZnO with different conduction band minimums (CBMs) used as an electron transport layer.

The voltage-luminance relationship for an electron-only device shown in FIG. 21 shows that the electron-only device used in the measurement represented in FIGS. 20 and 21 emits light at a drive voltage in excess of 6 V. It is hence understood that the device operates as an electron-only device at drive voltages lower than or equal to 6 V.

FIG. 22 is a diagram representing a relationship between a voltage and a current density in a hole-only device passing holes alone for each of NiO alone, a combination of NiO and an organic material, and an organic material alone used as a hole transport layer. Note that the vertical line in FIG. 22 indicates 3 V.

A hole-only device passing holes alone is capable of only injecting holes to the light-emitting layer with the injection of electrons to the light-emitting layer being blocked and is suitably used in analyzing the injection of holes to the light-emitting layer. Electric current is a flow of electric charges per time, and the injection of holes to the light-emitting layer can be estimated from the current density in the hole-only device.

In FIG. 22, the topmost line represents a hole-only device using PEDOT:PSS/PVK as a hole transport layer, the second line from the top represents a hole-only device using NiO/Al₂O₃/oxydiphthalic anhydride (ODPA) as a hole transport layer, the third line from the top represents a hole-only device using PEDOT:PSS/poly[(9,9-dioctylfluorenyl-2,7-diyl)-co-(4,4′-(N-(4-sec-butylphenyl))diphenylamine)] (TFB) as a hole transport layer, the fourth line from the top represents a hole-only device using NiO as a hole transport layer, the fifth line from the top represents a hole-only device using NiO/Al₂O₃ as a hole transport layer, the sixth line from the top represents a hole-only device using NiO/PVK as a hole transport layer, and the bottom line represents a hole-only device using NiO/TFB as a hole transport layer.

The voltage-current density relationship for the hole-only devices shown in FIG. 22 shows that the hole injection property in the injection of holes to the light-emitting layer tends to be highest in the hole transport layer made solely of an organic material and lowest in the hole transport layer made of an organic material and an inorganic material.

FIG. 23 is a diagram representing a relationship between a voltage and a luminance in a hole-only device passing holes alone for each of NiO alone, a combination of NiO and an organic material, and an organic material alone used as a hole transport layer.

The voltage-luminance relationship for a hole-only device shown in FIG. 23 shows that the hole-only device used in the measurement represented in FIGS. 22 and 23 emits light at a drive voltage in excess of 10 V. It is hence understood that the device operates as a hole-only device at drive voltages lower than or equal to 10 V.

It is understood that the QLED and the OLED, as an example, operate in an excess electron condition under operating conditions at or below 3 V, which is a typical emission-starting voltage for the QLED and the OLED, because the electron current density shown in FIG. 20 is approximately 10 times as high as the hole current density shown in FIG. 22.

Accordingly, this excess electron condition can be addressed by improving the hole injection property from the hole injection property in the injection of holes to the light-emitting layer shown in FIG. 22 by using the hole transport layer made solely of an organic material. However, it is understood that even when a hole transport layer is used that is made solely of an organic material although the approximate level thereof can be improved from the electron current density shown in FIG. 20 and the hole current density shown in FIG. 22 under operating conditions at or below 3 V, the QLED and the OLED still operate in an excess electron condition. Therefore, the hole transport layer made solely of an organic material inevitably receives excessive electrons and hence undergoes so much degradation that it is impossible to realize a light-emitting element with improved reliability.

In FIG. 24, (a), (b), and (c) are schematic band diagrams illustrating problems in a light-emitting element including a hole transport layer made solely of TFB (organic material) and an electron transport layer made of ZnO.

Portion (a) of FIG. 24 is a schematic band diagram before joining, (b) of FIG. 24 is a schematic band diagram after joining, and (c) of FIG. 24 is a schematic band diagram under an application voltage.

As shown in (c) of FIG. 24, the quantum dots (QDs) in the light-emitting layer are driven in an excess electron condition when the light-emitting element is driven. Therefore, an overflow of excessive electrons from the light-emitting layer to the hole transport layer is inevitable, and the hole transport layer (HTL) emits light, as well as the quantum dots (QDs) in the light-emitting layer emit light, which leads to a decrease in luminous efficiency. Additionally, the hole transport layer made solely of TFB (organic material) inevitably receives excessive electrons and hence undergoes so much degradation that it is impossible to realize a light-emitting element with improved reliability.

Accordingly, the inventors of the disclosure suggest a light-emitting element that has a structure including a region that exhibits a deep potential by which electrons are confined in a path extending from the electron transport layer to the light-emitting layer, to restrain injection of electrons to light-emitting sites.

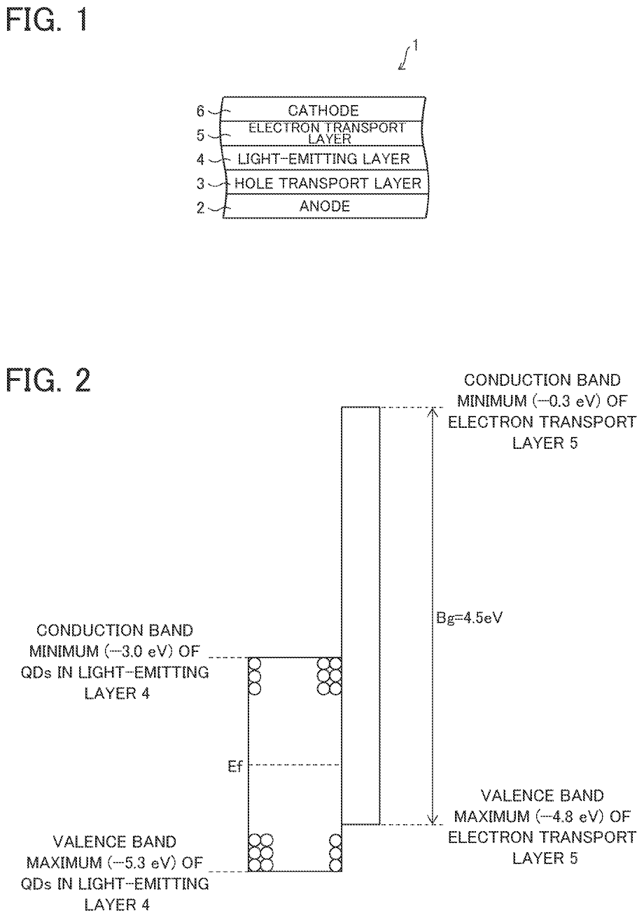

The following will describe embodiments of the disclosure with reference to FIGS. 1 to 17. Members of an embodiment that have the same function as members of a particular embodiment may be indicated by the same reference numerals, and description thereof be omitted.

### Embodiment 1

FIG. 1 is a schematic cross-sectional view of a structure of a light-emitting element 1 in accordance with Embodiment 1.

Referring to FIG. 1, the light-emitting element 1 includes: a cathode 6; an anode 2 disposed opposite the cathode 6; a light-emitting layer 4 between the cathode 6 and the anode 2; and an electron transport layer 5 between the cathode 6 and the light-emitting layer 4. Note that the electron transport layer 5 contains either a compound containing a Group IIB (12) element, a Group IVB (14) element, and elemental nitrogen or a compound containing a Group IVB (14) element, a Group VIB (16) element, and elemental boron (detailed later). The present embodiment takes an example where the light-emitting element 1 includes no electron injection layer between the electron transport layer 5 and the cathode 6. This is however not the only possible implementation of the disclosure. Alternatively, the light-emitting element 1 may further include an electron injection layer and any other intervening layers. In addition, the present embodiment takes an example where the light-emitting element 1 includes a hole transport layer 3 between the anode 2 and the light-emitting layer 4. This is however not the only possible implementation of the disclosure. Alternatively, the light-emitting element 1 may include a hole injection layer, in place of the hole transport layer 3, between the anode 2 and the light-emitting layer 4 and include any other intervening layers, for example, a hole injection layer in addition to the hole transport layer 3, between the anode 2 and the hole transport layer 3.

Note that Group 12 (current IUPAC) is an equivalent of Group IIB (defunct IUPAC) and also an equivalent of Group IIB (defunct CAS), that Group 14 (current IUPAC) is an equivalent of Group IVB (defunct IUPAC) and also an equivalent of Group IVA (defunct CAS), and that Group 16 (current IUPAC) is an equivalent of Group VIB (defunct IUPAC) and also an equivalent of Group VIA (defunct CAS). In this document, the groups of elements are given in accordance with the defunct IUPAC system (current IUPAC system).

In the present embodiment, the light-emitting element 1 is described, as an example, to include a stack of the anode 2, the hole transport layer 3, the light-emitting layer 4, the electron transport layer 5, and the cathode 6, all of which are provided in this order (forward-order stack structure). This is however not the only possible implementation of the disclosure. Alternatively, the light-emitting element 1 may include, for example, a stack of the cathode 6, the electron transport layer 5, the light-emitting layer 4, the hole transport layer 3, and the anode 2, all of which are provided in this order (reverse-order stack structure).

The light-emitting element 1 may be either a top-emission type or a bottom-emission type. As shown in FIG. 1, when the light-emitting element 1 includes a stack that has a forward-order stack structure, since the cathode 6 is disposed above the anode 2, the anode 2 is made of an electrode material that reflects visible light, and the cathode 6 is made of an electrode material that transmits visible light, to obtain a top-emission structure, and the anode 2 is made of an electrode material that transmits visible light, and the cathode 6 is made of an electrode material that reflects visible light, to obtain a bottom-emission structure. In contrast, when the light-emitting element 1 includes a stack that has a reverse-order stack structure, since the anode 2 is disposed above the cathode 6, the cathode 6 is made of an electrode material that reflects visible light, and the anode 2 is made of an electrode material that transmits visible light, to obtain a top-emission structure, and the anode 2 is made of an electrode material that reflects visible light, and the cathode 6 is made of an electrode material that transmits visible light, to obtain a bottom-emission structure (not shown).

The electrode material that reflects visible light is not limited in any particular manner provided that the material is reflective to visible light and electrically conductive. The electrode material that reflects visible light may be, for example, a metal material such as Al, Mg, Li, or Ag; an alloy of any of these metal materials; a stack of any of the metal materials and a transparent metal oxide (e.g., indium tin oxide, indium zinc oxide, or indium gallium zinc oxide); or a stack of the alloy and the transparent metal oxide.

Meanwhile, the electrode material that transmits visible light is not limited in any particular manner provided that the material is transmissive to visible light and electrically conductive. The electrode material that transmits visible light may be, for example, a thin film of a transparent metal oxide (e.g., indium tin oxide, indium zinc oxide, or indium gallium zinc oxide) or a thin film of a metal material such as Al, Mg, Li, or Ag.

The anode 2 and the cathode 6 may be formed by a common electrode-forming method including physical vapor deposition (PVD) such as vacuum vapor deposition, sputtering, EB vapor deposition, and ion plating and chemical vapor deposition (CVD). In addition, the anode 2 and the cathode 6 may be patterned by any method provided that the method is capable of producing a desired pattern with satisfactory precision. Specific examples of such a patterning method include photolithography and inkjet printing.

The hole transport layer 3 shown in FIG. 1 may be made of any hole transport material provided that the material is capable of stabilizing the transport of holes to the light-emitting layer 4. A preferred hole transport material has a high hole mobility. Furthermore, the hole transport material is preferably capable of preventing electrons from the cathode 6 from passing through (electron-blocking material). Hence, the hole-electron recombination efficiency can be enhanced in the light-emitting layer 4.

The hole transport layer 3 preferably contains an inorganic material, and this inorganic material may be, for example, an oxide containing one or more species selected from Zn, Ni, Mg, La, Mo, W, V, and Le. These metal oxides have higher chemical stability than organic materials, thereby further improving the reliability of the light-emitting element 1. The hole transport layer made of such a metal oxide produces conduction electrons due to oxygen deficiency and therefore enables suitable control of the oxygen deficiency density of a film by, for example, forming the film by sputtering under appropriate control of the oxygen concentration of the supply gas. Furthermore, the inorganic material may be, for example, either a Group II-VI compound semiconductor or a Group III-V compound semiconductor. By using either a Group II-VI compound semiconductor or a Group III-V compound semiconductor as the hole transport layer 3 in this manner, the reliability of the light-emitting element 1 can be improved over the reliability of the structure in which a hole transport layer made of an organic material is used. The present embodiment describes an example where the hole transport layer 3 is made of NiO. This is however not the only possible implementation of the disclosure. Alternatively, the hole transport layer 3 may be made of, for example, MgNiO or another inorganic material.

The present embodiment describes an example where only the NiO-made hole transport layer 3 is provided between the anode 2 and the light-emitting layer 4. This is however not the only possible implementation of the disclosure. Alternatively, either one or both of a hole transport layer and a hole injection layer may be provided between the anode 2 and the light-emitting layer 4, with either one or both of the hole transport layer and the hole injection layer containing an inorganic material. In this structure, either one or both of the hole transport layer and the hole injection layer contain(s) an inorganic material, which improves the reliability of the light-emitting element 1.

The light-emitting element 1, as detailed later, has a structure including a region that exhibits a deep potential by which electrons are confined in a path extending from the electron transport layer 5 to the light-emitting layer 4. Therefore, so few electrons overflow to the hole transport layer 3 that even if the hole transport layer 3 is made solely of am organic material, the resultant light-emitting element 1 can provide sufficient reliability. Examples of the organic material for the hole transport layer 3 include polyvinyl carbazole (PVK) and poly[(9,9-dioctylfluorenyl-2,7-diyl)-co-(4,4′-(N-(4-sec-butylphenyl))diphenylamine)] (TFB). However, these examples are not comprehensive or exhaustive.

In addition, the light-emitting element 1 may include a hole injection layer (not shown) between the anode 2 and the hole transport layer 3. The material for the hole injection layer may be any hole injecting material provided that the material is capable of stabilizing the injection of holes to the light-emitting layer 4. For example, PEDOT:PSS may be used as the hole injection layer.

The light-emitting element 1 may further include a passivation layer (not shown) between the hole transport layer 3 and the light-emitting layer 4. For example, Al₂O₃ may be used as the passivation layer.

The light-emitting layer 4 in the light-emitting element 1 shown in FIG. 1 contains quantum dots (QDs). “Quantum dots (QDs)” refers to dots with a maximum width of from 1 nm to 100 nm both inclusive. The shape of quantum dots is not limited in any particular manner so long as the shape has the aforementioned maximum width and is not necessarily spherical (cross-section is circular). Quantum dots may be shaped like, for example, a polygon in cross-section, a bar, or a branch, have an irregular surface, or have a combination of these shapes. The light-emitting layer 4 containing quantum dots (QDs) can be fabricated into any of, for example, a light-emitting layer that emits red light, a light-emitting layer that emits green light, and a light-emitting layer that emits blue light by one of the following configurations. Cores made of a single material, but having different particle diameters, may be used so that the light-emitting elements 1 including the light-emitting layer 4 containing quantum dots (QDs) can emit light of different colors. For example, cores with the largest particle diameter may be used in the light-emitting layer that emits red light, cores with the smallest particle diameter may be used in the light-emitting layer that emits blue light, and cores with a particle diameter between the particle diameter of the cores used in the light-emitting layer that emits red light and the particle diameter of the cores used in the light-emitting layer that emits blue light may be used in the light-emitting layer that emits green light. Alternatively, cores made of different materials may be used so that the light-emitting elements 1 including the light-emitting layer 4 containing quantum dots (QDs) can emit light of different colors.

The quantum dots (QDs) contained in the light-emitting layer 4 may be made of any material provided that the quantum dots (QDs) can exhibit a peak emission wavelength in the visible light range. For example, the quantum dots may be semiconductor quantum dots that exhibit a peak emission wavelength in any of the red-color range, the green-color range, and the blue-color range. Those materials which are commonly used for quantum dots may be used including II-VI compounds such as ZnSe, III-V compounds such as InP, chalcogenide, and perovskite.

The quantum dots (QDs) contained in the light-emitting layer 4 preferably have a core/shell structure. The quantum dots (QDs) contained in the light-emitting layer 4 may have a structure including cores alone, but preferably have a core/shell structure. The region that exhibits a deep potential by which electrons e are confined can be provided even if the quantum dots (QDs) have a structure including cores alone. However, when the quantum dots (QDs) have a structure including cores alone, the surface defects may not be sufficiently inactivated, possibly losing the electrons e confined in the regions that exhibit a deep potential through the defects. Meanwhile, when the quantum dots (QDs) have a core/shell structure, the quantum dots (QDs) have the defects thereof sufficiently inactivated, and very few electrons e are lost in non-emissive transitions. Therefore, a good confinement effect on electrons e is achieved. Specifically, as detailed later, the confinement effect can be enhanced on the electrons e in a first layer R1 of the light-emitting layer 4 that forms a region that exhibits a deep potential by which electrons e are confined. The “core/shell structure” refers to a structure that includes a core and a shell on the surface of the core. Preferably, the quantum dots have cores and shells covering at least a part of the surface of the cores. Note that the shells particularly preferably cover the entire cores. In addition, the quantum dots (QDs) contained in the light-emitting layer 4 preferably have organic or inorganic ligands. The quantum dots (QDs), having suitable organic or inorganic ligands, can improve dispersibility in an application (coating) solvent. The quantum dots (QDs) have a particle diameter that, although being variable depending on the emission wavelength and material, is often generally approximately in a range from a few nanometers to a few tens of nanometers in which the quantum confinement effect (detailed later) is feasible.

The electron transport layer 5 in the light-emitting element 1 shown in FIG. 1 significantly bends the band of the light-emitting layer 4 containing quantum dots (QDs) to form a region that exhibits a deep, electron-confining potential in the light-emitting layer 4.

FIG. 2 is a schematic band diagram for the light-emitting layer 4 and the electron transport layer 5 in the light-emitting element 1 in accordance with Embodiment 1. Note that in FIG. 2, “Ef” denotes the Fermi level.

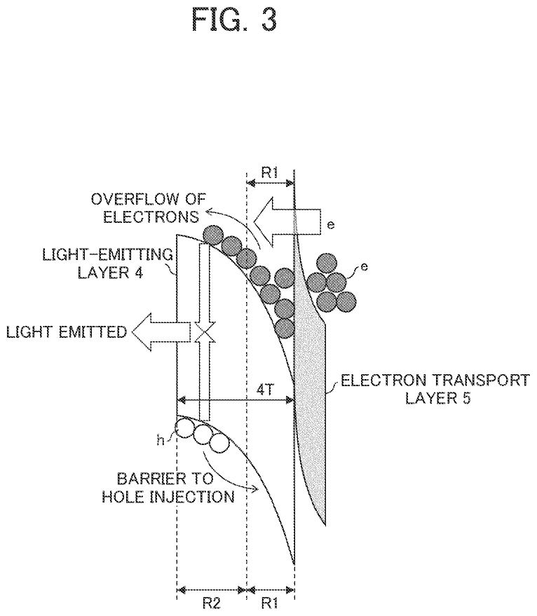

FIG. 3 is a schematic band diagram when the light-emitting layer 4 and the electron transport layer 5 in the light-emitting element 1 in accordance with Embodiment 1 are joined.

In the present embodiment, as shown in FIG. 1, the electron transport layer 5 is described, as an example, as being in contact with the light-emitting layer 4. This is however not the only possible implementation of the disclosure. Alternatively, there may be provided an insulating layer between the light-emitting layer 4 and the electron transport layer 5 as in Embodiment 2 (detailed later). In the structure where the light-emitting layer 4 containing quantum dots (QDs) is in contact with the electron transport layer 5, the region that exhibits a deep, electron-confining potential can be formed in the light-emitting layer 4 without having to include an additional layer.

The present embodiment discusses an example, as shown in FIG. 2, using: quantum dots (QDs) having a valence band maximum of −5.3 eV and a conduction band minimum of −3.0 eV; and the electron transport layer 5 containing ZnSiN₂, which is an n-type semiconductor, and having a conduction band minimum of −0.3 eV, a valence band maximum of −4.8 eV, and a band gap Bg of 4.5 eV. This is however not the only possible implementation of the disclosure. As described earlier, the quantum dots (QDs) may be made of any material provided that the quantum dots (QDs) exhibit a peak emission wavelength in the visible light range. The electron transport layer 5 may be made of any material provided that the absolute value of the difference of the conduction band minimum of the electron transport layer 5 from the vacuum energy level is smaller than the absolute value of the difference of the conduction band minimum of the quantum dots (QDs) in the light-emitting layer 4 from the vacuum energy level.

Note that in the description of the schematic band diagrams, the numerical figure for energy is negative in value, but the absolute value thereof is equal to the absolute value of the difference from the vacuum energy level. When the band is described as being deep or shallow, the absolute value of the difference from the vacuum energy level (absolute value of the numerical figure for energy) may be alternately described as being large or small respectively. Furthermore, the absolute value of the difference between the vacuum energy level and the conduction band minimum may be alternately termed the electron affinity. In addition, the absolute value of the difference between the vacuum energy level and the valence band maximum may be alternately termed the ionization potential.

Referring to FIG. 3, when the light-emitting layer 4 and the electron transport layer 5 are joined, the band of the light-emitting layer 4 significantly bends across the thickness direction under the influence of the electron transport layer 5. This is because the electrons e in the electron transport layer 5 have a higher concentration than the electrons e in the light-emitting layer 4. The light-emitting layer 4 includes: the first layer R1 in contact with the electron transport layer 5; and a second layer R2 in contact with the first layer R1 and separated from the electron transport layer 5. The band of the first layer R1 in the light-emitting layer 4 that is in contact with the electron transport layer 5 and that forms a region that exhibits a deep, electron-confining potential is bent more than the band of the second layer R2 in the light-emitting layer 4 that is separated from the electron transport layer 5 and that emits light.

In the injection of electrons e from the electron transport layer 5 to the first layer R1 in the light-emitting layer 4 where a region is formed that exhibits a deep potential by which electrons e are confined, after the electrons e fill the first layer R1 in the light-emitting layer 4 where a region is formed that exhibits a deep potential, the number of electrons e that have moved beyond the first layer R1 in the light-emitting layer 4 where a region is formed that exhibits a deep potential and reached the second layer R2 in the light-emitting layer 4 is injected anew from the electron transport layer 5 to the first layer R1 in the light-emitting layer 4. In other words, after the electrons e fill the first layer R1 in the light-emitting layer 4 where a region is formed that exhibits a deep potential, the same number of electrons e move into and out of the first layer R1 in the light-emitting layer 4. The first layer R1 in the light-emitting layer 4 has an electron density of approximately from 10¹⁵ atoms/cm³ to 10¹⁶ atoms/cm³. Electrons approximately at least 100 times this electron density need to be injected for the electrons e to overflow from the first layer R1 in the light-emitting layer 4. In the light-emitting element 1 including the first layer R1 in the light-emitting layer 4 where a region is formed that exhibits a deep potential by which the electrons e are confined, the second layer R2, in the light-emitting layer 4, that emits light under a typical drive voltage does not experience an excess electron condition. The number of electrons e that move beyond the first layer R1 in the light-emitting layer 4 and that reach the second layer R2 in the light-emitting layer 4 is approximately 1/10 the number of electrons e confined in the first layer R1 in the light-emitting layer 4. The rest of the electrons e remain in the first layer R1 in the light-emitting layer 4. Note that electrons e are injected to the first layer R1 in the light-emitting layer 4 by tunnelling through a thin Schottky barrier.

The first layer R1 in the light-emitting layer 4 where a region is formed that exhibits a deep potential by which electrons e are confined, even if being light-emissive, does not need to be made non-emissive for the following reason. As shown in FIG. 3, the band of the first layer R1 in the light-emitting layer 4 that is in contact with the electron transport layer 5 and that forms a region that exhibits a deep, electron-confining potential is significantly bent. Therefore, the holes h injected from the anode 2 to the light-emitting layer 4 via the hole transport layer 3 are confined in the second layer R2 in the light-emitting layer 4 by a high barrier formed on a valence band side of the first layer R1 in the light-emitting layer 4. As described here, the first layer R1 in the light-emitting layer 4 contains only electrons e and no holes h as carriers. Therefore, no recombination of electrons e and holes h, hence no emission of light, occurs. Therefore, the first layer R1 in the light-emitting layer 4 forms a region that exhibits a deep potential by which electrons e are confined without being lost.

The second layer R2 in the light-emitting layer 4 confines the holes h injected from the anode 2 to the light-emitting layer 4 via the hole transport layer 3 and is fed with overflowing electrons approximately 1/10 the number of electrons e confined in the first layer R1 in the light-emitting layer 4. Therefore, in the second layer R2 in the light-emitting layer 4, electrons e and holes h recombine, thereby emitting light. Thus, it is only the second layer R2 that emits light in the light-emitting layer 4.

As described above, under operating conditions at or below 3 V, which is a typical emission-starting voltage for the QLED and the OLED, the electron current density (see FIG. 20) is approximately 10 times as high as the hole current density (see FIG. 22), and therefore, it is understood that the light-emitting element 1 operates in an excess electron condition where the number of electrons e is approximately 10 times as large as the number of holes h.

The light-emitting element 1 in accordance with the present embodiment includes: the cathode 6; the anode 2 disposed opposite the cathode 6; the light-emitting layer 4 between the cathode 6 and the anode 2; and the electron transport layer 5 between the cathode 6 and the light-emitting layer 4. The electron transport layer 5 contains either a compound containing a Group IIB (12) element, a Group IVB (14) element, and elemental nitrogen or a compound containing a Group IVB (14) element, a Group VIB (16) element, and elemental boron. In this configuration, the electron transport layer 5 and the light-emitting layer 4 have a desirable band structure. For this reason, the charge-carrier balance of electrons e and holes h in the light-emitting layer 4 is significantly improved, and the resultant light-emitting element 1 exhibits an improved luminous efficiency. In addition, since this improvement of the charge-carrier balance in the light-emitting layer 4 significantly reduces the number of electrons e that flow out to the hole transport layer 3 side, the hole transport layer 3 can be restrained from being degraded even if the hole transport layer 3 is made of an organic material. Furthermore, if the hole transport layer 3 is made of an inorganic material, the degradation is further restrained. Therefore, the resultant light-emitting element 1 exhibits improved reliability.

The light-emitting element 1 in accordance with the present embodiment includes: the cathode 6; the anode 2 disposed opposite the cathode 6; the light-emitting layer 4 containing quantum dots (QDs) between the cathode 6 and the anode 2; and the electron transport layer 5 of an n-type semiconductor between the cathode 6 and the light-emitting layer 4, the electron transport layer 5 being in contact with the light-emitting layer 4, the absolute value of the difference of the conduction band minimum of the electron transport layer 5 from the vacuum energy level being smaller than the absolute value of the difference of the conduction band minimum of the light-emitting layer 4 from the vacuum energy level. The light-emitting layer 4 includes: the first layer R1 in contact with the electron transport layer 5; and the second layer R2 in contact with the first layer R1 and separated from the electron transport layer 5. Only the second layer R2 emits light in the light-emitting layer 4. According to this configuration, approximately 1/10 the number of electrons e confined in the first layer R1 in the light-emitting layer 4 overflow into the second layer R2 in the light-emitting layer 4. Therefore, in the second layer R2 in the light-emitting layer 4, the charge-carrier balance of electrons e and holes h is significantly improved, and the resultant light-emitting element 1 exhibits improved luminous efficiency. In addition, since this improvement of the charge-carrier balance significantly reduces the number of electrons e that flow out to the hole transport layer 3 side, the hole transport layer 3 can be restrained from being degraded even if the hole transport layer 3 is made of an organic material. Furthermore, if the hole transport layer 3 is made of an inorganic material, the degradation is further restrained. Therefore, the resultant light-emitting element 1 exhibits improved reliability.

Note that the light-emitting layer 4 preferably has a thickness of from 20 nm to 100 nm both inclusive. The formation of the light-emitting layer 4 with a thickness of 20 nm or more enables restraining non-uniform emission of light, and the formation of the light-emitting layer 4 with a thickness of 100 nm or less enables restraining the luminous efficiency from decreasing.

The second layer R2 in the light-emitting layer 4 preferably has a thickness less than or equal to half the thickness (4T) of the light-emitting layer 4. The thickness 4T of the light-emitting layer 4 is the addition of the thickness of the first layer R1 in the light-emitting layer 4 and the thickness of the second layer R2 in the light-emitting layer 4. In the light-emitting layer 4 containing quantum dots (QDs), the thickness of the second layer R2 is preferably from approximately 10 nm to approximately 50 nm both inclusive. The thickness of the second layer R2 containing quantum dots (QDs) is controllable through, for example, the particle diameter of the quantum dots (QDs) and application (coating) conditions. If the thickness of the second layer R2 exceeds 50 nm, the thickness is longer than the diffusion length of the injected holes, and there are cases where the luminous efficiency may therefore decrease. On the other hand, if the thickness is less than 10 nm, there are cases where the second layer R2 may not be formed with a uniform thickness across the entire light-emitting element 1, which could lead to non-uniform emission of light.

Since the first layer R1 in the light-emitting layer 4 and the second layer R2 in the light-emitting layer 4 are made of the same type of quantum dots (QDs) in the present embodiment, the present embodiment discusses, as an example, the first layer R1 and the second layer R2 being formed by forming the light-emitting layer 4. This is however not the only possible implementation of the disclosure. Alternatively, for example, the first layer R1 in the light-emitting layer 4 and the second layer R2 in the light-emitting layer 4 may be made of different types of quantum dots (QDs), in which case the first layer R1 in the light-emitting layer 4 and the second layer R2 in the light-emitting layer 4 are formed with a prescribed thickness in different steps. Note that when the first layer R1 in the light-emitting layer 4 and the second layer R2 in the light-emitting layer 4 are made of the same type of quantum dots (QDs), and the first layer R1 and the second layer R2 are formed by forming the light-emitting layer 4, as is the case of the present embodiment, the thickness of the second layer R2 is controllable through the control of the total thickness of the light-emitting layer 4. Since the second layer R2 in the light-emitting layer 4 is a light-emitting layer, and the first layer R1 in the light-emitting layer 4 is a non-light-emitting layer, even when the first layer R1 in the light-emitting layer 4 and the second layer R2 in the light-emitting layer 4 are made of the same type of quantum dots (QDs), the thickness of the second layer R2 in the light-emitting layer 4 can be measured.

Referring to FIG. 3, to bend the band of the first layer R1 in the light-emitting layer 4 where a region is formed that exhibits a deep potential by which electrons e are confined, the electron transport layer 5 preferably has the shallowest possible conduction band minimum (CBM) and the highest possible free electron density. The absolute value of the difference of the conduction band minimum of the electron transport layer 5 from the vacuum energy level is preferably smaller than 0.3 eV. This configuration enables forming the first layer R1 in the light-emitting layer 4 where a region that exhibits a deep potential by which electrons e are confined is formed on the light-emitting layer 4 side through the joining with the light-emitting layer 4.

An example of such materials is a compound containing a Group IIB (12) element, a Group IVB (14) element, and elemental nitrogen. The electron transport layer 5 may be suitably made of, for example, a compound containing Zn (Group IIB (12) element), a Group IVB (14) element, and elemental nitrogen, a compound containing a Group IIB (12) element, one species selected from Si, Ge, and Sn (Group IVB (14) element), and elemental nitrogen, a compound containing a Group IIB (12) element, two or more species selected from Si, Ge, and Sn (Group IVB (14) element), and elemental nitrogen, a compound containing Zn (Group IIB (12) element), one species selected from Si, Ge, and Sn (Group IVB (14) element), and elemental nitrogen, or a compound containing Zn (Group IIB (12) element), two or more species selected from Si, Ge, and Sn (Group IVB (14) element), and elemental nitrogen.

The provision of the electron transport layer 5 containing one of these compounds imparts a desirable band structure to the electron transport layer 5 and the light-emitting layer 4.

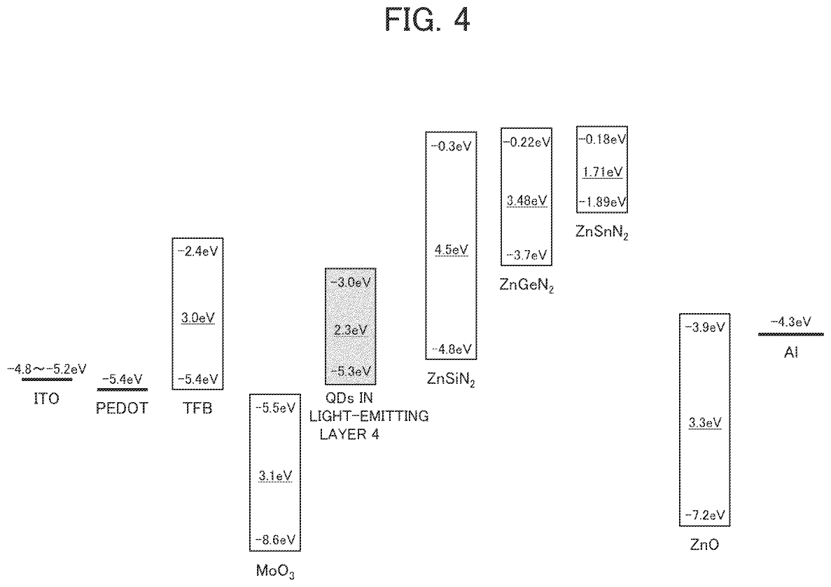

FIG. 4 is a diagram illustrating an example of a material that can be used as the electron transport layer 5 in the light-emitting element 1 in accordance with Embodiment 1.

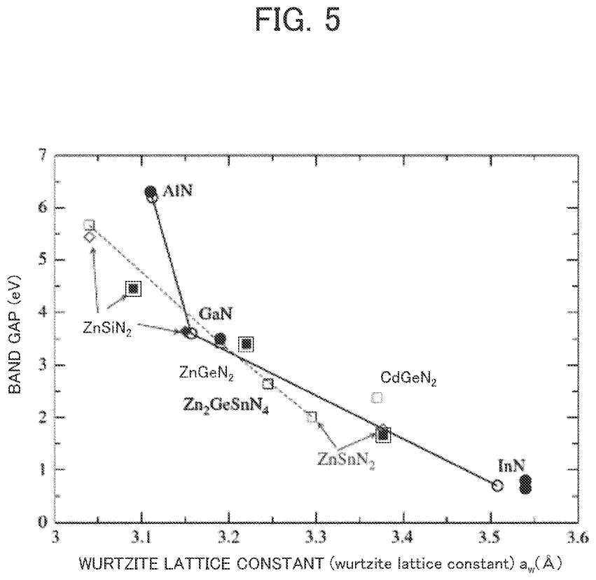

FIG. 5 is a diagram representing a relationship between the band gap and the wurtzite lattice constant a_{w} of exemplary materials that can be used as the electron transport layer 5 in the light-emitting element 1 in accordance with Embodiment 1 (reproduced from a non-Patent Literature: III-Nitride Semiconductors and Their Modern Devices by Bernard Gil, Series on Semiconductor Science and Technology, Oxford University Press, 2013).

FIG. 4 shows a schematic band diagram for ZnSnN₂, ZnGeN₂, and ZnSiN₂ as examples of a compound containing Zn (Group IIB (12) element), a Group IVB (14) element, and elemental nitrogen. ZnSiN₂ is used as the electron transport layer 5 in the present embodiment.

The compound containing Zn (Group IIB (12) element), a Group IVB (14) element, and elemental nitrogen is a hexagonal crystal with the Group IIIB (13) element in a nitride semiconductor such as GaN being replaced alternately by Zn (Group IIB (12)) and a Group IVB (14) element. Zn (Group IIB (12) element) and a Group IVB (14) element have three valance electrons on average and hence have a structure that is overall quasi-identical to a nitride. From this structure, the compound has a relatively deep valence band maximum (VBM) due to a high electronegativity of nitrogen and a shallow conduction band minimum (CBM) due to the Group IVB (14) element. Particularly, the shallow conduction band minimum (CBM) due to the Group IVB (14) element is very shallow when compared with the conduction band minimum (CBM) of, for example, ZnO. As shown in FIG. 4, ZnSnN₂ has a conduction band minimum (CBM) of −0.18 eV, ZnGeN₂ has a conduction band minimum (CBM) of −0.22 eV, and ZnSiN₂ has a conduction band minimum (CBM) of −0.3 eV. In addition, CdGeN₂ has a conduction band minimum (CBM) that is approximately equal to the conduction band minimum (CBM) of ZnSnN₂ (not shown). Meanwhile, as shown in FIG. 4, ZnSnN₂ has a valence band maximum (VBM) of −1.89 eV, ZnGeN₂ has a valence band maximum (VBM) of −3.7 eV, and ZnSiN₂ has a valence band maximum (VBM) of −4.8 eV. In addition, CdGeN₂ has a valence band maximum (VBM) that is approximately equal to the valence band maximum (VBM) of ZnSnN₂ (not shown).

Referring to FIG. 5, the band gap of the semiconductive region is shown for the compound containing Zn (Group IIB (12) element), one species selected from Si, Ge, and Sn (Group IVB (14) element), and elemental nitrogen and the compound containing Zn (Group IIB (12) element), two or more species selected from Si, Ge, and Sn (Group IVB (14) element), and elemental nitrogen. These compounds are known to exhibit n-type conduction when not doped, have a carrier density in excess of 10¹⁸ atoms/cm³, and are characterized by their pseudo-degenerate properties at normal temperature.

The compounds preferably have these properties in the formation of the first layer R1 in the light-emitting layer 4 where a region is formed that exhibits a deep potential by which electrons e are confined. Therefore, the electron transport layer 5 is preferably an n-type semiconductor. In addition, the electron transport layer 5 is preferably a degenerate semiconductor. Note that a “degenerate semiconductor” refers to a semiconductor with a Fermi level in either the conduction band or the valence band. When the electron transport layer 5 is either an n-type semiconductor or a degenerate semiconductor, the difference between the ionization potential of the cathode 6 and the ionization potential of the electron transport layer 5 can be increased, and these two can be joined by a thin Schottky junction. In addition, electrons can be injected from the cathode 6 by tunnelling effect with small contact resistance.

This carrier density, in other words, the high free electron density, of the compound containing Zn (Group IIB (12) element), one species selected from Si, Ge, and Sn (Group IVB (14) element), and elemental nitrogen and the compound containing Zn (Group IIB (12) element), two or more species selected from Si, Ge, and Sn (Group IVB (14) element), and elemental nitrogen can be possibly caused by free electrons produced due to atom deficiency among other causes. Typically, nitrogen deficient possibly occurs, for example, at 10¹⁷ atoms/cm³ to 10²⁰ atoms/cm³ both inclusive.

Referring to FIG. 4, there is a very large difference between the conduction band minimum (CBM) of the quantum dots (QDs) contained in the light-emitting layer 4 and the conduction band minimum (CBM) of ZnSnN₂, the conduction band minimum (CBM) of ZnGeN₂, or the conduction band minimum (CBM) of ZnSiN₂ as the electron transport layer 5. When these two layers with significantly differing conduction band minimums (CBMs) are joined, electrons move from the electron transport layer 5, which has a shallow conduction band minimum (CBM) and a pseudo-degenerate Fermi level to the quantum dots (QDs) contained in the light-emitting layer 4, so that the Fermi level of the joined member including the two layers with significantly differing conduction band minimums (CBMs) matches the pseudo-intrinsic Fermi level of the quantum dots (QDs) contained in the light-emitting layer 4. As a result, as shown in FIG. 3, the band of the joined member including the two layers with significantly differing conduction band minimums (CBMs) is significantly bent, so that a region where the potential is deep can be formed in the first layer R1 in the light-emitting layer 4 containing quantum dots (QDs) that have almost no free carriers. Since this deep-potential region formed in the first layer R1 in the light-emitting layer 4 containing quantum dots (QDs) produces a very high barrier to the holes h injected from the anode 2, the holes h can be efficiently confined in the second layer R2 in the light-emitting layer 4 containing quantum dots (QDs). In contrast, the pseudo-degenerate electron transport layer 5 produces a high barrier in a limited region on a side near the first layer R1 in the light-emitting layer 4 containing quantum dots (QDs). However, this barrier is so thin that electrons e can readily tunnel through the barrier under an application voltage.

By joining the light-emitting layer 4 containing quantum dots (QDs) and the electron transport layer 5 as described in the foregoing, the first layer R1 in the light-emitting layer 4 where a region is formed that exhibits a deep potential by which electrons e are confined can be formed, and the resultant first layer R1 produces a high barrier to the holes h injected from the hole transport layer 3 side and does not disrupt the injection of electrons e from the electron transport layer 5.

The present embodiment has so far discussed an example where the ratio of the Group IIB (12) element, the Group IVB (14) element, and the elemental nitrogen in the compound contained in the electron transport layer 5, such as ZnSiN₂, ZnGeN₂, Zn₂GeSnN₄, ZnSnN₂, and CdGeN₂ shown in FIG. 5, is equal to 1:1:2. This is however for illustrative purposes only and not the only possible implementation of the disclosure.

The compound contained in the electron transport layer 5 needs only to be of chemical formula (1), AₓD_{y}N_{z}, where A is a Group IIB (12) element, D is a Group IVB (14) element, N is elemental nitrogen, x is a numerical value from 0.75 to 1.25 both inclusive, y is a numerical value from 0.75 to 1.25 both inclusive, and z is a numerical value from 1.5 to 2.5 both inclusive.

The maximum proportion of the elemental nitrogen is set to 2.5 or less for the following reasons. If the elemental nitrogen is excessive (z>2.5), the Group IIB (12) element is insufficient (x<0.75), and the Group IVB (14) element is insufficient (y<0.75). The acceptors in the Group IIB (12) element and the acceptors in the Group IVB (14) element could hence possibly compensate for electrons, thereby imparting high resistance and moving the Fermi level Ef close to intrinsic. The setting of the maximum proportion of the elemental nitrogen to 2.5 or less would restrain these problems.

Meanwhile, the minimum proportion of the elemental nitrogen is set to 1.5 or more for the following reasons. If the elemental nitrogen is insufficient (z<1.5), the Group IIB (12) element is excessive (x>1.25), and the Group IVB (14) element is excessive (y>1.25). This condition could cause precipitation of either the Group IIB (12) element or the Group IVB (14) element. The regions where either the Group IIB (12) element or the Group IVB (14) element has precipitated in this manner would exhibit metallic conduction, possibly causing leak or disrupting the injection of electrons e to the light-emitting layer 4. The setting of the minimum proportion of the elemental nitrogen to 1.5 or more would restrain these problems.

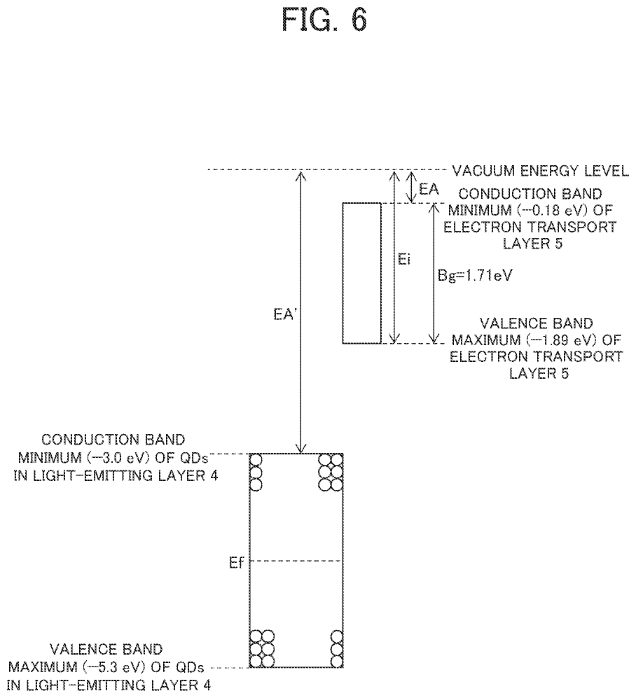

FIG. 6 is a schematic band diagram for an alternative electron transport layer in the light-emitting element 1 in accordance with Embodiment 1.

FIG. 6 is a schematic band diagram when the electron transport layer 5 used contains ZnSnN₂ which is an n-type semiconductor with a conduction band minimum of −0.18 eV, a valence band maximum of −1.89 eV, and a band gap Bg of 1.71 eV.

Referring to FIG. 6, the electron transport layer 5 has an ionization potential Ei (1.89 eV) and an electron affinity EA (0.18) both of which are lower than the electron affinity EA′ (3.0 eV) of the quantum dots (QDs) contained in the light-emitting layer 4 and also exhibits a band gap (Bg=1.71 eV). In this configuration, the electron transport layer 5 and the light-emitting layer 4 have a desirable band structure. For this reason, the charge-carrier balance of electrons e and holes h in the light-emitting layer 4 is significantly improved, and the resultant light-emitting element 1 exhibits an improved luminous efficiency. In addition, since this improvement of the charge-carrier balance in the light-emitting layer 4 significantly reduces the number of electrons e that flow out to the hole transport layer 3 side, the hole transport layer 3 can be restrained from being degraded even if the hole transport layer 3 is made of an organic material. Furthermore, if the hole transport layer 3 is made of an inorganic material, the degradation is further restrained. Therefore, the resultant light-emitting element exhibits improved reliability.

The electron affinity EA of the electron transport layer 5 is preferably lower than or equal to 1 eV. In addition, the ionization potential Ei of the electron transport layer 5 is preferably less than or equal to 2.55 eV. By joining this electron transport layer 5 and the light-emitting layer 4 containing quantum dots (QDs), the first layer R1 in the light-emitting layer 4 where a region is formed that exhibits a deep potential by which electrons e are confined can be formed, and the resultant first layer R1 produces a high barrier to the holes h injected from the hole transport layer 3 side and does not disrupt the injection of electrons e from the electron transport layer 5.

The description has so far discussed an example where the electron transport layer 5 contains a compound containing a Group IIB (12) element, a Group IVB (14) element, and elemental nitrogen. This is however not the only possible implementation of the disclosure. Alternatively, the electron transport layer 5 may contain a compound containing a Group IVB (14) element, a Group VIB (16) element, and elemental boron.

Compounds containing a Group IVB (14) element, a Group VIB (16) element, and elemental boron have a structure in which boron, which is a Group IIIB (13) element with the highest electronegativity and the smallest ionic radius, is common, and the Group VB (15) element is replaced alternately by a Group IVB (14) element and a Group VIB (16) element. From this structure, the compound has a relatively deep valence band maximum (VBM) due to the high electronegativity of boron and also has a shallow conduction band minimum (CBM) due to the Group IVB (14) element. Note that the Group VIB (16) element is preferably one or more species selected from S, Se, and O which have a relatively small ionic radius.

By the provision of the electron transport layer 5 containing the above-described compound, the electron transport layer 5 and the light-emitting layer 4 have a desirable band structure. For this reason, the charge-carrier balance of electrons e and holes h in the light-emitting layer 4 is significantly improved, and the resultant light-emitting element 1 exhibits an improved luminous efficiency. In addition, since this improvement of the charge-carrier balance in the light-emitting layer 4 significantly reduces the number of electrons e that flow out to the hole transport layer 3 side, the hole transport layer 3 can be restrained from being degraded even if the hole transport layer 3 is made of an organic material. Furthermore, if the hole transport layer 3 is made of an inorganic material, the degradation is further restrained. Therefore, the resultant light-emitting element 1 exhibits improved reliability.

The ratio of the Group IVB (14) element, the Group VIB (16) element, and the elemental boron in the compound contained in the electron transport layer 5 may be equal to 1:1:2. This is however for illustrative purposes only and not the only possible implementation of the disclosure.

Note that Group 13 (current IUPAC) is an equivalent of Group IIIB (defunct IUPAC) and also an equivalent of Group IIIA (defunct CAS). Group 15 (current IUPAC) is an equivalent of Group VB (defunct IUPAC) and also an equivalent of Group VA (defunct CAS).

The compound contained in the electron transport layer 5 needs only to be of chemical formula (2), DₓE_{y}B_{z}, where D is a Group IVB (14) element, E is a Group VIB (16) element, B is elemental boron, x is a numerical value from 0.75 to 1.25 both inclusive, y is a numerical value from 0.75 to 1.25 both inclusive, and z is a numerical value from 1.5 to 2.5 both inclusive.

The maximum proportion of the elemental boron is set to 2.5 or less for the following reasons. If the elemental boron is excessive (z>2.5), the Group IVB (14) element is insufficient (x<0.75), and the Group VIB (16) element is insufficient (y<0.75). This condition could cause more elemental boron to move into gaps between lattices. Therefore, metallic or semi-metallic conduction occurs, possibly causing leak or disrupting the injection of electrons e to the light-emitting layer 4. The acceptors in the Group IVB (14) element and the acceptors in the Group VIB (16) element could hence possibly compensate for electrons, thereby imparting high resistance and moving the Fermi level Ef close to intrinsic. The setting of the maximum proportion of the elemental boron to 2.5 or less would restrain these problems.

Meanwhile, the minimum proportion of the elemental boron is set to 1.5 or more for the following reasons. If the elemental boron is insufficient (z<1.5), the Group IVB (14) element is excessive (x>1.25), and the Group VIB (16) element is excessive (y>1.25), This condition could cause precipitation of either the Group IVB (14) element or the Group VIB (16) element. The regions where either the Group IVB (14) element or the Group VIB (16) element has precipitated in this manner would exhibit metallic conduction, possibly causing leak or disrupting the injection of electrons e to the light-emitting layer 4. The setting of the minimum proportion of the elemental boron to 1.5 or more would restrain these problems.

By joining the electron transport layer 5 containing a compound containing a Group IVB (14) element, a Group VIB (16) element, and elemental boron and the light-emitting layer 4 containing quantum dots (QDs) as described in the foregoing, the first layer R1 in the light-emitting layer 4 where a region is formed that exhibits a deep potential by which electrons e are confined can be formed, and the resultant first layer R1 produces a high barrier to the holes h injected from the hole transport layer 3 side and does not disrupt the injection of electrons e from the electron transport layer 5.

In addition, there may be provided an electron injection layer (not shown) between the cathode 6 and the electron transport layer 5. Any material may be used in the electron injection layer provided that the material is an electron injecting material that can stabilize the injection of electrons to the light-emitting layer 4. As the electron injection layer, for example, alkali metal or alkali earth metal, such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, and polymethyl methacrylate polystyrene sodium sulfonate, oxide of alkali metal or alkali earth metal, fluoride of alkali metal or alkali earth metal, or an organic complex of alkali metal may be used.

The hole injection layer (not shown), the hole transport layer 3, the electron transport layer 5, and the electron injection layer (not shown) may be formed by, for example, any method including vapor deposition, printing, inkjet printing, spin coating, casting, dipping, bar coating, blade coating, roll coating, gravure coating, flexo printing, spray coating, photolithography, or self-assembling (layer-by-layer adsorption and self-assembled monolayer method). These examples are for illustrative purposes only. Preferred examples among these are vapor deposition, spin coating, inkjet printing, and photolithography.

The light-emitting layer 4 containing quantum dots (QDs) may be formed by, for example, spin coating or inkjet printing a colloidal solution of quantum dots (QDs) dispersed in a solvent. Alternatively, quantum dots (QDs) may be dispersed in a resist and patterned by photolithography.

The light-emitting element 1 in accordance with the present embodiment includes the electron transport layer 5 between the cathode 6 and the light-emitting layer 4, and the electron transport layer 5 contains either a compound containing a Group IIB (12) element, a Group IVB (14) element, and elemental nitrogen or a compound containing a Group IVB (14) element, a Group VIB (16) element, and elemental boron. The electron transport layer 5 containing this compound has a very shallow conduction band minimum and a Fermi level close to the conduction band minimum and has a high free electron density. By using such an electron transport layer 5, the first layer R1 in the light-emitting layer 4 where a region is formed that exhibits a deep potential by which electrons e is confined can be formed in a path extending from the electron transport layer 5 to the light-emitting layer 4. The electrons e injected from the electron transport layer 5 are stored in a region that exhibits a deep potential due to the high barrier produced by the very shallow conduction band minimum in a region where the potential is deep. Only some of the electrons e that have high energy overflow and are injected to the second layer R2 in the light-emitting layer 4, which enables restraining the injection of electrons e from a region where the potential is deep to the second layer R2 in the light-emitting layer 4.

Meanwhile, the holes h injected from the anode 2 side to the second layer R2 in the light-emitting layer 4 are confined in the second layer R2 in the light-emitting layer 4 by the high barrier produced by the valence band maximum in the region where the potential is deep.

By injecting only some electrons e that have high energy, out of the electrons e injected from the electron transport layer 5 to the first layer R1 in the light-emitting layer 4, to the second layer R2 in the light-emitting layer 4 while confining the holes h injected from the anode 2 side to the second layer R2 in the light-emitting layer 4 in the second layer R2 in the light-emitting layer 4 as described in the foregoing, the charge-carrier balance of electrons e and holes h can be improved in the light-emitting second layer R2 in the light-emitting layer 4, and the resultant light-emitting element 1 exhibits a high luminous efficiency.

Note that in the present embodiment, the first layer R1 in the light-emitting layer 4 where a region is formed that exhibits a deep potential by which electrons e are confined is formed by forming the electron transport layer 5 and the light-emitting layer 4 containing quantum dots (QDs) that have a conduction band minimum and a Fermi level that significantly differ from the conduction band minimum and the Fermi level of the electron transport layer 5 respectively, in such a manner that the electron transport layer 5 and the light-emitting layer 4 are in direct contact with each other. This is however for illustrative purposes only and not the only possible implementation of the disclosure.

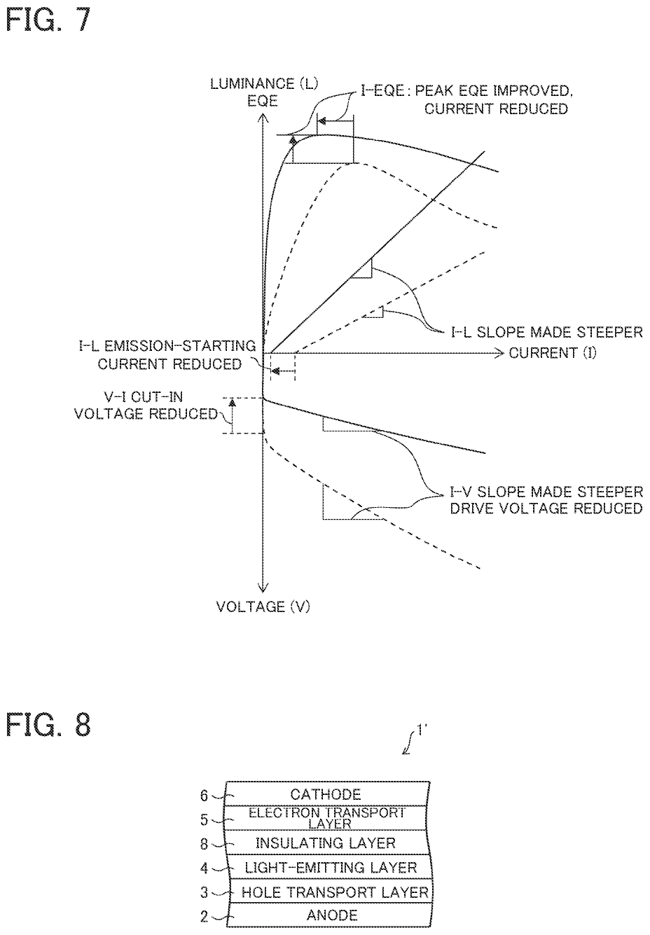

FIG. 7 is a diagram illustrating properties of the light-emitting element 1 in accordance with Embodiment 1.

In FIG. 7, solid lines indicate the properties of the light-emitting element 1, whereas dotted lines indicate the properties of a light-emitting element in accordance with a comparative example that includes ZnO as a electron transport layer in place of the electron transport layer 5 in the light-emitting element 1. From the relationship between electric current (I) and EQE (external quantum efficiency), the EQE at the same electric current value is higher in the light-emitting element 1 than in the light-emitting element in accordance with the comparative example, and the peak EQE is achieved at lower electric current in the light-emitting element 1 than in the light-emitting element in accordance with the comparative example. Therefore, the light-emitting element 1 has a higher luminous efficiency than the light-emitting element in accordance with the comparative example. In addition, from the relationship between electric current (I) and luminance (L), the I-L emission-starting current is successfully reduced, and the I-L slope is successfully made steep, in the light-emitting element 1 over in the light-emitting element in accordance with the comparative example. Furthermore, from the relationship between electric current (I) and voltage (V), the V-I cut-in voltage is successfully reduced, and the drive voltage is successfully reduced by restraining the I-V slope from being increasing, in the light-emitting element 1 over in the light-emitting element in accordance with the comparative example.

### Embodiment 2

A description is given next of Embodiment 2 of the disclosure with reference to FIG. 8. A light-emitting element 1′ in accordance with the present embodiment differs from the light-emitting element 1 described in Embodiment 1 in that an insulating layer 8 having a thickness of 5 nm or less is provided between the light-emitting layer 4 and the electron transport layer 5, that the electron transport layer 5 and the insulating layer 8 are in contact with each other, and that the insulating layer 8 and the light-emitting layer 4 are in contact with each other. Embodiment 2 is otherwise the same as Embodiment 1. For convenience of description, members of the present embodiment that have the same function as members shown in drawings for Embodiment 1 are indicated by the same reference numerals, and description thereof is omitted.

FIG. 8 is a schematic cross-sectional view of a structure of the light-emitting element 1′ in accordance with Embodiment 2.

Referring to FIG. 8, in the light-emitting element 1′, the insulating layer 8 having a thickness of 5 nm or less is interposed between the light-emitting layer 4 and the electron transport layer 5, the electron transport layer 5 and the insulating layer 8 are in contact with each other, and the insulating layer 8 and the light-emitting layer 4 are in contact with each other. The thickness of the insulating layer 8 needs to allow the tunnelling of electrons e, and Al₂O₃ is formed with a thickness of 5 nm in the present embodiment, which is an example for illustrative purposes only. The provision of the insulating layer 8 between the light-emitting layer 4 and the electron transport layer 5 enables inactivation of defects on the interface of the electron transport layer 5 that is in contact with the insulating layer 8 and on the interface of the light-emitting layer 4 that is in contact with the insulating layer 8.

In the light-emitting element 1′, the conduction band minimum (CBM) of the quantum dots (QDs) contained in the light-emitting layer 4 significantly differs from the conduction band minimum (CBM) of the electron transport layer 5. When these two layers which have significantly differing conduction band minimums (CBMs) are joined so as to sandwich the insulating layer 8 having a thickness of 5 nm or less, electrons e from the electron transport layer which has a shallow conduction band minimum (CBM) and a pseudo-degenerate Fermi level tunnel through the insulating layer 8 and move to the quantum dots (QDs) contained in the light-emitting layer 4. Therefore, the Fermi level of the joined member including the light-emitting layer 4, the insulating layer 8, and the electron transport layer 5 matches the pseudo-intrinsic Fermi level of the quantum dots (QDs) contained in the light-emitting layer 4. As a result, the band of the joined member including the light-emitting layer 4, the insulating layer 8, and the electron transport layer 5 is significantly bent, so that a region where the potential is deep can be formed in the first layer (not shown) that is in contact with the insulating layer 8 in the light-emitting layer 4 containing quantum dots (QDs) that have almost no free carriers. Since this deep-potential region formed in the first layer in the light-emitting layer 4 containing quantum dots (QDs) produces a very high barrier to the holes h injected from the anode 2, the holes h can be efficiently confined in that second layer (not shown) in the light-emitting layer 4 containing quantum dots (QDs) which is in contact with the hole transport layer 3. In contrast, the pseudo-degenerate electron transport layer 5 produces a high barrier in a limited region on a side near the insulating layer 8. However, this barrier is so thin that electrons e can readily tunnel through the barrier under an application voltage.

By joining the light-emitting layer 4 containing quantum dots (QDs) and the electron transport layer 5 so as to sandwich the insulating layer 8 as described in the foregoing, the first layer in the light-emitting layer 4 where a region is formed that exhibits a deep potential by which electrons e are confined can be formed, and the resultant first layer R1 produces a high barrier to the holes h injected from the hole transport layer 3 side and does not disrupt the injection of electrons e from the electron transport layer 5.

This configuration improves charge-carrier balance. The resultant light-emitting element 1′ has improved luminous efficiency and improved reliability.

### Embodiment 3

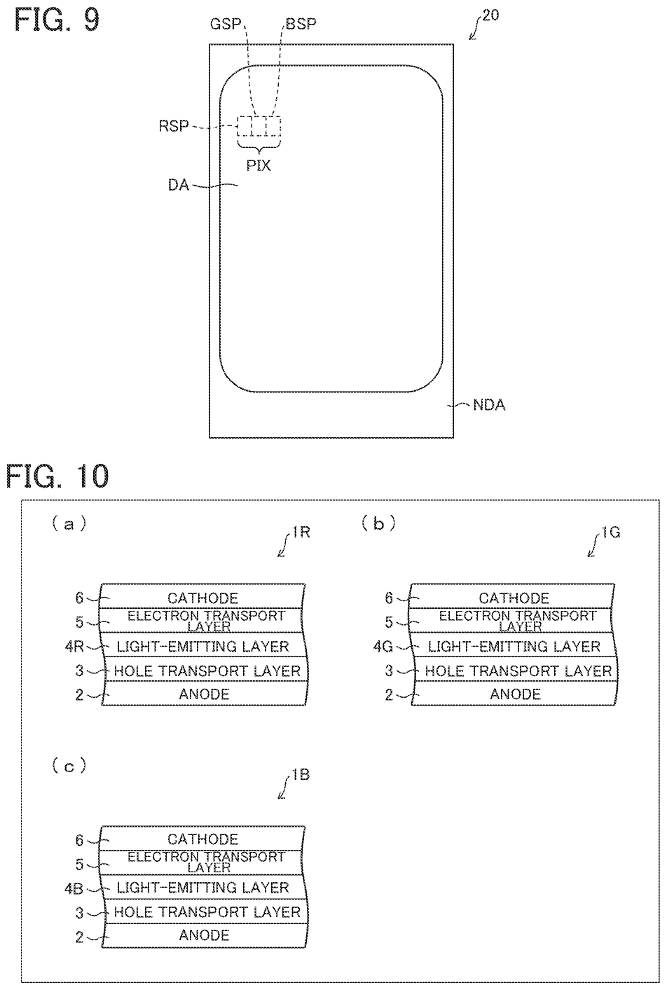

A description is given next of Embodiment 3 of the disclosure with reference to FIGS. 9 and 10. A light-emitting element 1R, a light-emitting element 1G, and a light-emitting element 1B in accordance with the present embodiment include different light-emitting layers 4R, 4G, and 4B, but include electron transport layers 5 made of the same material. For convenience of description, members of the present embodiment that have the same function as members shown in drawings for Embodiments 1 and 2 are indicated by the same reference numerals, and description thereof is omitted.

FIG. 9 is a schematic diagram representing a structure of a display device 20 including the light-emitting element 1R, the light-emitting element 1G, and the light-emitting element 1B.

In FIG. 10, (a) is a schematic cross-sectional view of a structure of the light-emitting element 1R in a red subpixel RSP in the display device 20 shown in FIG. 9, (b) is a schematic cross-sectional view of a structure of the light-emitting element 1G in a green subpixel GSP in the display device 20 shown in FIG. 9, and (c) is a schematic cross-sectional view of a structure of the light-emitting element 1B in a blue subpixel BSP in the display device 20 shown in FIG. 9.

Referring to FIG. 9, the display device 20 includes a frame area NDA and a display area DA. The display area DA of the display device 20 includes a plurality of pixels PIX. Each pixel PIX includes one red subpixel RSP, one green subpixel GSP, and one blue subpixel BSP. The present embodiment discusses an example where each pixel PIX includes one red subpixel RSP, one green subpixel GSP, and one blue subpixel BSP. This is however not the only possible implementation of the disclosure. Alternatively, for example, each pixel PIX may include a subpixel of another color in addition to the red subpixel RSP, the green subpixel GSP, and the blue subpixel BSP.

Each red subpixel RSP in the display device 20 includes the light-emitting element 1R shown in (a) of FIG. 10. Each green subpixel GSP in the display device 20 includes the light-emitting element 1G shown in (b) of FIG. 10. Each blue subpixel BSP in the display device 20 includes the light-emitting element 1B shown in (c) of FIG. 10.

The quantum dots (QDs) contained in a light-emitting layer 4R in the light-emitting element 1R, the quantum dots (QDs) contained in a light-emitting layer 4G in the light-emitting element 1G, and the quantum dots (QDs) contained in a light-emitting layer 4B in the light-emitting element 1B may be formed using cores made of the same material, but having different particle diameters. For example, cores with the largest particle diameter may be used in the light-emitting layer 4R that emits red light, cores with the smallest particle diameter may be used in the light-emitting layer 4B that emits blue light, and cores with a particle diameter between the particle diameter of the cores used in the light-emitting layer 4R that emits red light and the particle diameter of the cores used in the light-emitting layer 4B that emits blue light may be used in the light-emitting layer 4G that emits green light.

Alternatively, the quantum dots (QDs) contained in the light-emitting layer 4R in the light-emitting element 1R, the quantum dots (QDs) contained in the light-emitting layer 4G in the light-emitting element 1G, and the quantum dots (QDs) contained in the light-emitting layer 4B in the light-emitting element 1B may be formed using cores made of different materials.

The present embodiment discusses an example where each of the light-emitting layer 4R, the light-emitting layer 4G, and the light-emitting layer 4B includes quantum dots (QDs) having a core and a shell with a peak emission wavelength in the visible light range. This is however not the only possible implementation of the disclosure. Alternatively, for example, the quantum dots (QDs) in each of the light-emitting layer 4R, the light-emitting layer 4G, and the light-emitting layer 4B do not necessarily have a core/shell structure and may have a core-only structure, provided that the quantum dots (QDs) exhibit a peak emission wavelength in the visible light range. When the quantum dots (QDs) in each of the light-emitting layer 4R, the light-emitting layer 4G, and the light-emitting layer 4B have a core/shell structure with a peak emission wavelength in the visible light range, the quantum dots (QDs) have the defects thereof sufficiently inactivated so that very few electrons e are lost in non-emissive transitions. Therefore, a good confinement effect on electrons e is achieved.

The magnitude of the band gap energy of each of the light-emitting layer 4R, the light-emitting layer 4G, and the light-emitting layer 4B is the magnitude of energy determined from equation A below when the wavelength (λ) is in the visible light range.

E=hc/λ (equation A)

where E is energy (eV), λ is a wavelength (nm), h is Planck's constant, and c is the speed of light.

According to the above-mentioned structure, each of the light-emitting layer 4R, the light-emitting layer 4G, and the light-emitting layer 4B has an emission wavelength in the visible light range and a band gap in accordance with this.

In the present embodiment, as shown in (a) of FIG. 10, (b) of FIG. 10, and (c) of FIG. 10, the light-emitting element 1R, the light-emitting element 1G, and the light-emitting element 1B respectively include the light-emitting layer 4R, the light-emitting layer 4G, and the light-emitting layer 4B that exhibit different peak emission wavelengths and include the electron transport layer 5 made of the same material. Therefore, to restrain the electron transport layer 5 made of the same material from absorbing the light emitted by the light-emitting layer 4R, the light-emitting layer 4G, and the light-emitting layer 4B that exhibit different peak emission wavelengths, the magnitude of the band gap energy of the electron transport layer 5 made of the same material is preferably larger than the magnitude of the energy determined from equation A above when the wavelength (λ) is equal to 450 nm. In other words, the magnitude of the band gap energy of the electron transport layer 5 made of the same material is preferably specified in such a manner that the electron transport layer 5 does not absorb the blue light emitted by the light-emitting layer 4B which is the most energy-intense light. This configuration enables restraining the electron transport layer 5 made of the same material from absorbing the light emitted by the light-emitting layer 4R, the light-emitting layer 4G, and the light-emitting layer 4B that exhibit different peak emission wavelengths.

As shown in (a) of FIG. 10, (b) of FIG. 10, and (c) of FIG. 10, each of the light-emitting element 1R, the light-emitting element 1G, and the light-emitting element 1B includes the electron transport layer 5 made of the same material. Therefore, in the process of manufacturing the display device 20 including the light-emitting element 1R, the light-emitting element 1G, and the light-emitting element 1B, the electron transport layer 5 does not need to be formed repeatedly in a different step for each of the light-emitting elements 1R, 1G, and 1B and can be formed in a common step for all the light-emitting elements 1R, 1G, and 1B. Therefore, the number of steps involved in the manufacture of the display device 20 can be reduced.

The present embodiment has so far discussed an example where each of the light-emitting element 1R, the light-emitting element 1G, and the light-emitting element 1B includes the electron transport layer 5 made of the same material. This is however not the only possible implementation of the disclosure. Alternatively, each light-emitting element may include an electron transport layer 5 made of a different material as in Embodiment 5 detailed later.

### Embodiment 4

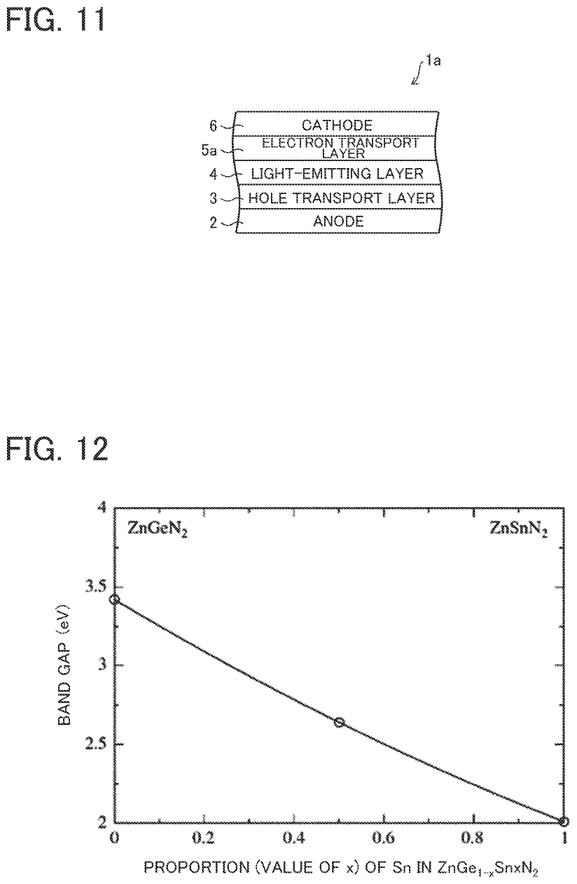

A description is given next of Embodiment 4 of the disclosure with reference to FIGS. 11 to 13. A light-emitting element 1a in accordance with the present embodiment differs from the light-emitting elements described in Embodiments 1 to 3 in that the Group IVB (14) element contained in the electron transport layer 5a contains two or more species selected from Si, Ge, and Sn. Embodiment 4 is otherwise the same as Embodiments 1 to 3. For convenience of description, members of the present embodiment that have the same function as members shown in drawings for Embodiments 1 to 3 are indicated by the same reference numerals, and description thereof is omitted.

FIG. 11 is a schematic cross-sectional view of a structure of the light-emitting element 1a.

Referring to FIG. 11, the light-emitting element 1a includes the electron transport layer 5a between the light-emitting layer 4 and the cathode 6.

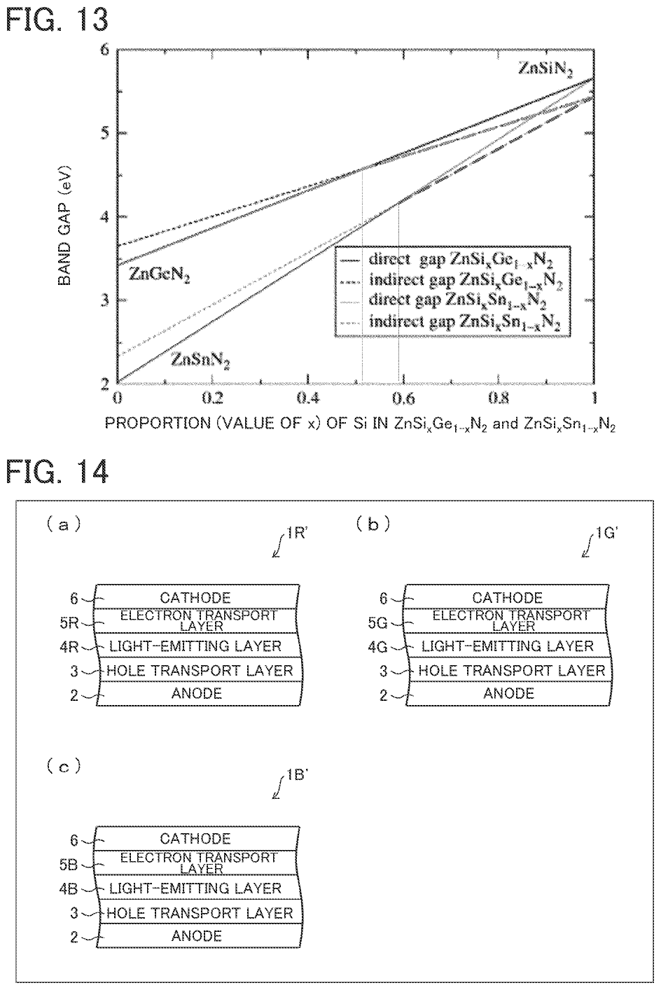

FIGS. 12 and 13 are diagrams illustrating the electron transport layer 5a in the light-emitting element 1a (reproduced from a non-Patent Literature: III-Nitride Semiconductors and Their Modern Devices by Bernard Gil, Series on Semiconductor Science and Technology, Oxford University Press, 2013).

FIG. 12 is a diagram representing a relationship between the proportion (value of x) of Sn in ZnGe₁₋ₓSnₓN₂ and the band gap.

Referring to FIG. 12, when the electron transport layer 5a contains, for example, a compound containing a Group IIB (12) element, a Group IVB (14) element, and elemental nitrogen, and the Group IVB (14) element contains Ge and Sn, the band gap becomes narrower as Sn accounts for a larger proportion of the compound (as Ge accounts for a smaller proportion). In the electron transport layer 5a, as Sn accounts for a larger proportion of the compound (as Ge accounts for a smaller proportion), the band gap becomes narrower, whereas the conduction band minimum (CBM) hardly changes, and the free electron density remains high. Therefore, when the electron transport layer 5a is used, almost the same effect of forming a region that exhibits a deep potential by which electrons e are confined in a path extending from the electron transport layer 5a to the light-emitting layer 4 can be achieved as when the electron transport layer 5 already described in Embodiment 1 is used.

FIG. 13 is a diagram representing a relationship between the proportion (value of x) of Si in ZnSiₓGe₁₋ₓN₂ and ZnSiₓSn₁₋ₓN₂ and the band gap. Note that FIG. 13 shows both the direct gap and the indirect gap.

Referring to FIG. 13, when the electron transport layer 5a contains, for example, a compound containing a Group IIB (12) element, a Group IVB (14) element, and elemental nitrogen, and the Group IVB (14) element contains Si and Ge or contains Si and Sn, the band gap becomes wider as Si accounts for a larger proportion of the compound. In The electron transport layer 5a, as Si accounts for a larger proportion, the band gap becomes wider, whereas the conduction band minimum (CBM) hardly changes, and the free electron density remains high. Therefore, when the electron transport layer 5a is used, almost the same effect of forming a region that exhibits a deep potential by which electrons e are confined in a path extending from the electron transport layer 5a to the light-emitting layer 4 can be achieved as when the electron transport layer 5 already described in Embodiment 1 is used.

By using as the electron transport layer 5a a compound in which the Group IVB (14) element is a mixed crystal as described in the foregoing, the band gap of the electron transport layer 5a can be relatively easily controlled.

The present embodiment has so far discussed an example where the electron transport layer 5a contains a compound containing a Group IIB (12) element, a Group IVB (14) element, and elemental nitrogen, and the Group IVB (14) element contained in the electron transport layer 5a contains two or more species selected from Si, Ge, and Sn. This is however not the only possible implementation of the disclosure. Alternatively, the electron transport layer 5a may contain a Group IVB (14) element, a Group VIB (16) element, and elemental boron, and the Group VIB (16) element contained in the electron transport layer 5a may contain two or more species selected from S, Se, and O.

### Embodiment 5

A description is given next of Embodiment 5 of the disclosure with reference to FIGS. 9 and 14. A light-emitting element 1R′, a light-emitting element 1G′, and a light-emitting element 1B′ in accordance with the present embodiment differ from the light-emitting elements 1R, 1G, and 1B described in Embodiment 3 in that the light-emitting elements 1R′, 1G′, and 1B′ include different light-emitting layers 4R, 4G, and 4B respectively and include different electron transport layers 5R, 5G, and 5B respectively. Embodiment 5 is otherwise the same as Embodiment 3. For convenience of description, members of the present embodiment that have the same function as members shown in drawings for Embodiment 3 are indicated by the same reference numerals, and description thereof is omitted.

In FIG. 14, (a) is a schematic cross-sectional view of a structure of the light-emitting element 1R′ in a red subpixel RSP in the display device 20 shown in FIG. 9, (b) is a schematic cross-sectional view of a structure of the light-emitting element 1G′ in a green subpixel GSP in the display device 20 shown in FIG. 9, and (c) is a schematic cross-sectional view of a structure of the light-emitting element 1B′ in a blue subpixel BSP in the display device 20 shown in FIG. 9.

The light-emitting element 1R′ shown in (a) of FIG. 14 includes a light-emitting layer 4R having a peak emission wavelength in the red-color range. The electron transport layer 5R contains ZnSnN₂ (e.g., with a band gap of 1.71 eV).

The light-emitting element 1G′ shown in (b) of FIG. 14 includes a light-emitting layer 4G having a peak emission wavelength in the green-color range. The electron transport layer 5G contains ZnGeN₂ (e.g., with a band gap of 3.48 eV).

The light-emitting element 1B′ shown in (c) of FIG. 14 includes a light-emitting layer 4B having a peak emission wavelength in the blue-color range. The electron transport layer 5B contains ZnSiN₂ (e.g., with a band gap of 4.5 eV).

The present embodiment has so far discussed an example where the electron transport layer 5R is made of ZnSnN₂, the electron transport layer 5G is made of ZnGeN₂, and the electron transport layer 5B is made of ZnSiN₂. This is however not the only possible implementation of the disclosure. Alternatively, the electron transport layer 5R, the electron transport layer 5G, and the electron transport layer 5B may be made of materials suitably selected from those materials which exhibit a band gap energy with a greater magnitude than the magnitude (1.63 eV) of energy determined from equation A above when the wavelength (λ) is equal to 760 nm.

The provision of the electron transport layers 5R, 5G, and 5B optimized to the peak emission wavelengths of the light-emitting layers 4R, 4G, and 4B in each of the light-emitting elements 1R′, 1G′, and 1B′ as described in the foregoing enables further restraining the electron transport layers 5R, 5G, and 5B from absorbing the light emitted by the light-emitting layers 4R, 4G, and 4B.

### Embodiment 6

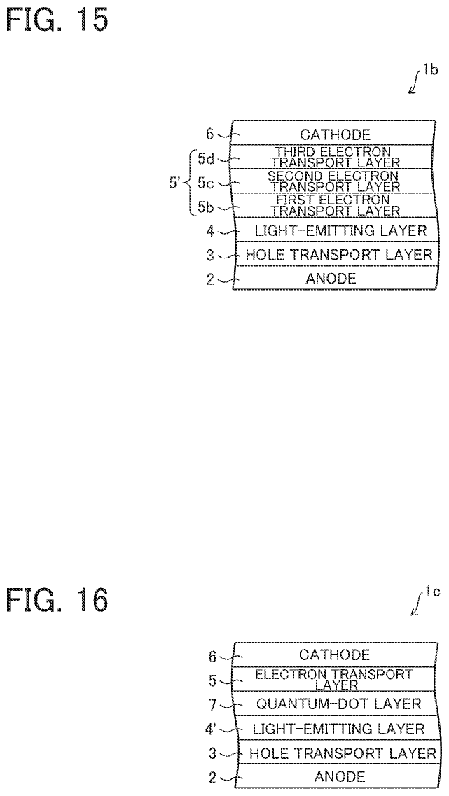

A description is given next of Embodiment 6 of the disclosure with reference to FIG. 15. Alight-emitting element 1b in accordance with the present embodiment differs from the light-emitting elements described in Embodiments 1 to 5 in that the light-emitting element 1b includes, as an electron transport layer 5′, a first electron transport layer 5b, a second electron transport layer 5c, and a third electron transport layer 5d, all of which are provided in this order when viewed from the light-emitting layer 4, that the third electron transport layer 5d has a lower electron affinity than the second electron transport layer 5c, and that the second electron transport layer 5c has a lower electron affinity than the first electron transport layer 5b. Embodiment 6 is otherwise the same as Embodiments 1 to 5. For convenience of description, members of the present embodiment that have the same function as members shown in drawings for Embodiments 1 to 5 are indicated by the same reference numerals, and description thereof is omitted.

FIG. 15 is a schematic cross-sectional view of a structure of the light-emitting element 1b.

Referring to FIG. 15, the light-emitting element 1b includes, as the electron transport layer 5′, the first electron transport layer 5b, the second electron transport layer 5c, and the third electron transport layer 5d, all of which are provided in this order when viewed from the light-emitting layer 4. The third electron transport layer 5d has a lower electron affinity than the second electron transport layer 5c. The second electron transport layer 5c has a lower electron affinity than the first electron transport layer 5b.

The present embodiment discusses an example where the third electron transport layer 5d is made of ZnSnN₂ (e.g., with an electron affinity of 0.18 eV), the second electron transport layer 5c is made of ZnGeN₂ (e.g., with an electron affinity of 0.22 eV), and the first electron transport layer 5b is made of ZnSiN₂ (e.g., with an electron affinity of 0.3 eV). These examples are however for illustrative purposes only.

In the light-emitting element 1b, the electrons injected from the cathode 6 face a stair-like barrier in the third electron transport layer 5d, the second electron transport layer 5c, and the first electron transport layer 5b, so as to reduce the drive voltage of the light-emitting element 1b.

The present embodiment has so far discussed an example where the first electron transport layer 5b, the second electron transport layer 5c, and the third electron transport layer 5d are stacked as the electron transport layer 5′. This is however not the only possible implementation of the disclosure. Alternatively, the electron transport layer 5′ may include the first electron transport layer 5b and the second electron transport layer 5c, which are provided in this order when viewed from the light-emitting layer 4, and the second electron transport layer 5c may have a lower electron affinity than the first electron transport layer 5b. In this configuration, for example, the first electron transport layer 5b may be made of ZnSiN₂, and the second electron transport layer 5c may be made of ZnGeN₂ or ZnSnN₂. As another alternative, the first electron transport layer 5b may be made of ZnGeN₂, and the second electron transport layer 5c may be made of ZnSnN₂.

### Embodiment 7

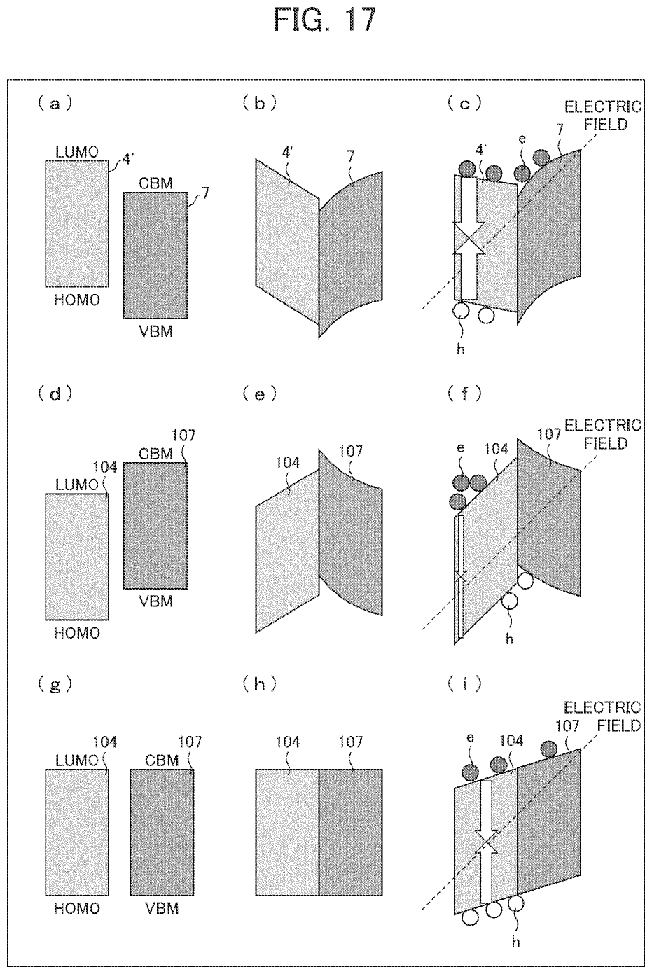

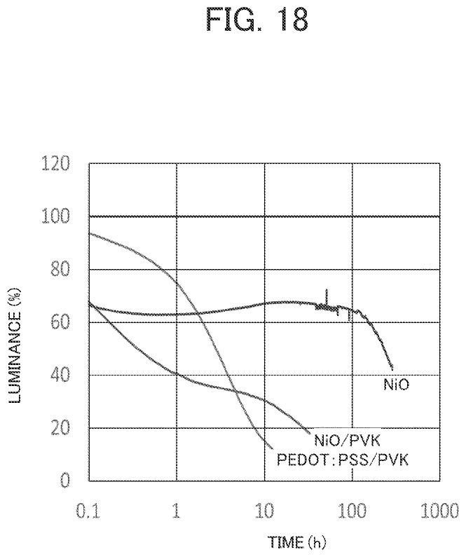

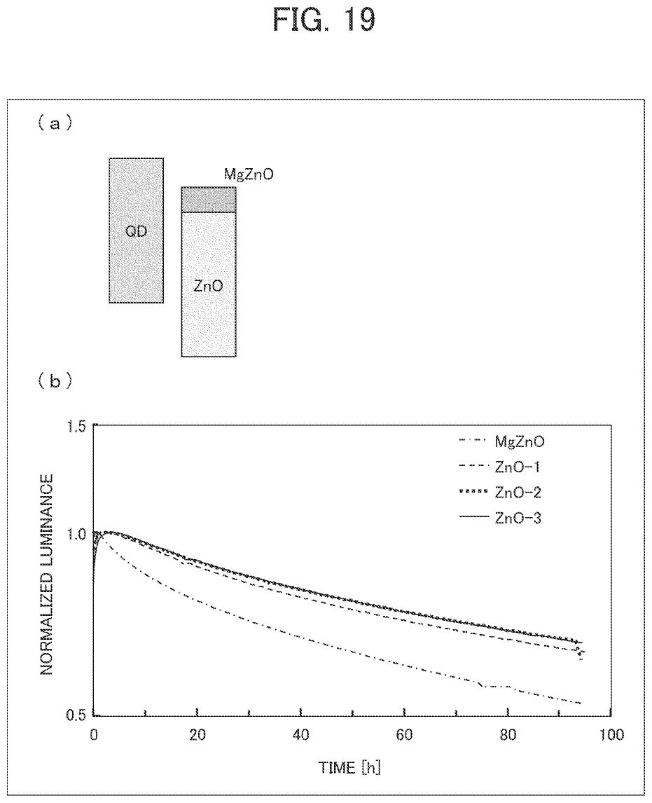

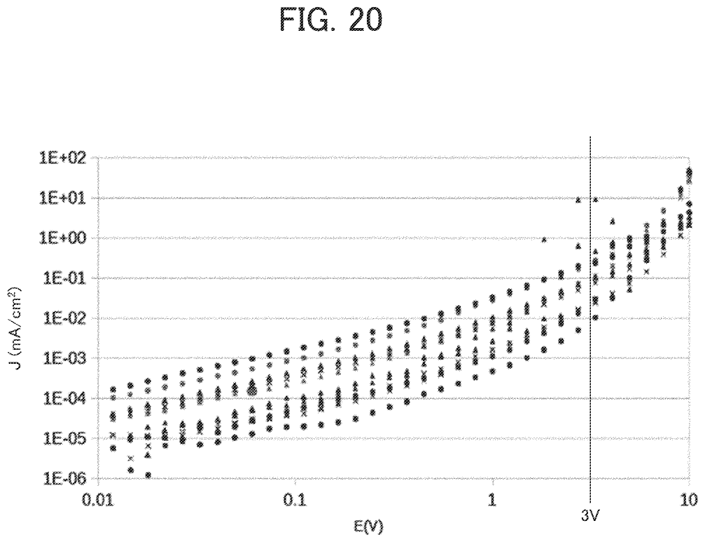

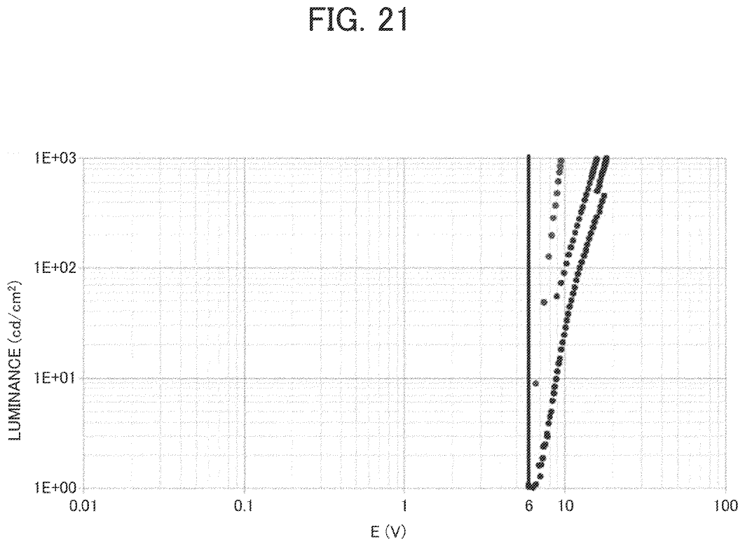

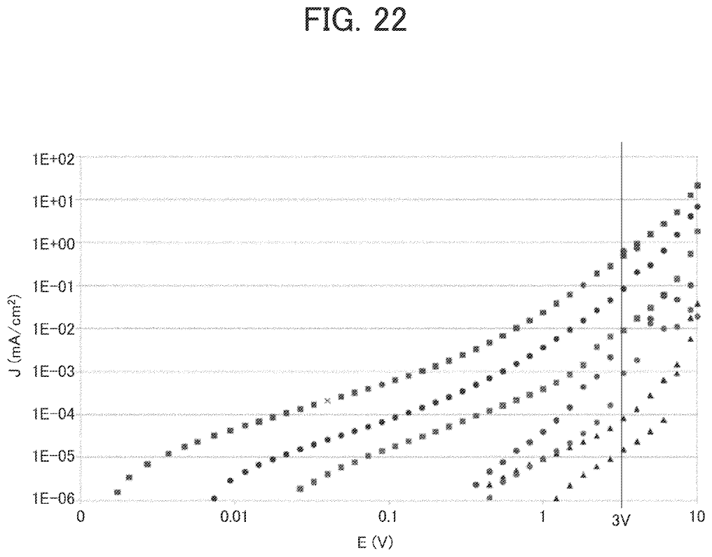

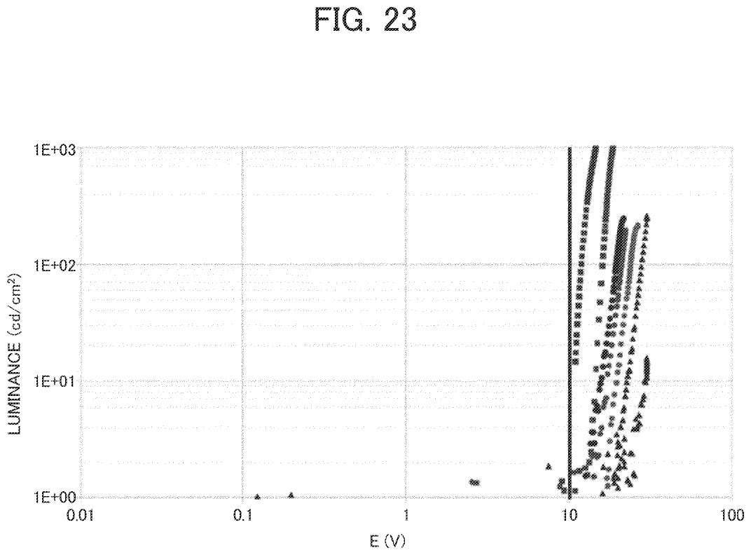

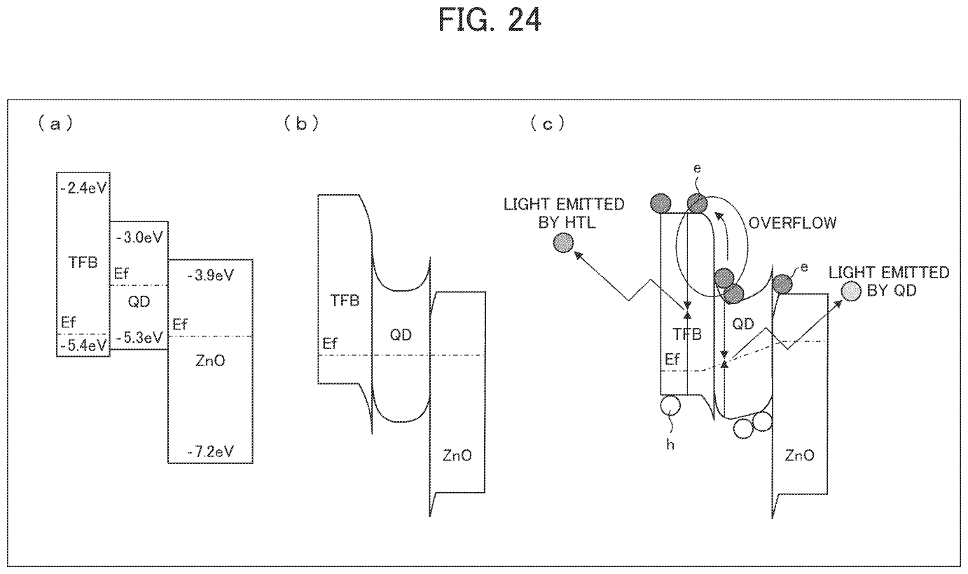

A description is given next of Embodiment 7 of the disclosure with reference to FIGS. 16 and 17. A light-emitting element 1c in accordance with the present embodiment differs from the light-emitting elements described in Embodiments 1 to 6 in that the light-emitting element 1c includes a light-emitting layer made of an organic material containing no quantum dots (QDs) as a light-emitting layer 4′ and further includes a quantum-dot layer 7 containing quantum dots (QDs) between the light-emitting layer 4′ and the electron transport layer 5. Embodiment 7 is otherwise the same as Embodiments 1 to 6. For convenience of description, members of the present embodiment that have the same function as members shown in drawings for Embodiments 1 to 6 are indicated by the same reference numerals, and description thereof is omitted.

FIG. 16 is a schematic cross-sectional view of a structure of the light-emitting element 1c.

Referring to FIG. 16, the light-emitting element 1c includes: a light-emitting layer made of an organic material containing no quantum dots (QDs) as the light-emitting layer 4; and the quantum-dot layer 7 containing quantum dots (QDs) between the light-emitting layer 4′ and the electron transport layer 5. The electron transport layer 5 and the quantum-dot layer 7 are in contact with each other, and the quantum-dot layer 7 and the light-emitting layer 4′ are also in contact with each other.

Note that the combined thickness of the light-emitting layer 4′ and the quantum-dot layer 7 is preferably from 20 nm to 100 nm both inclusive. The 20-nm or greater combined thickness of the light-emitting layer 4′ and the quantum-dot layer 7 enables restraining non-uniform light emission. The 100-nm or smaller combined thickness of the light-emitting layer 4′ and the quantum-dot layer 7 enables restraining decreases in luminous efficiency.

In FIG. 17, (a) is a schematic band diagram for the quantum-dot layer 7 and the light-emitting layer 4′ when the quantum-dot layer 7 and the light-emitting layer 4′ are not joined, (b) is a schematic band diagram for the quantum-dot layer 7 and the light-emitting layer 4′ when the quantum-dot layer 7 and the light-emitting layer 4′ are joined, and (c) is a schematic band diagram for the quantum-dot layer 7 and the light-emitting layer 4′ when the quantum-dot layer 7 and the light-emitting layer 4′ are under an application voltage.

As shown in (c) of FIG. 17, in the light-emitting element 1c, the region, described in Embodiment 1 above, that exhibits a deep potential by which electrons e are confined is formed in the quantum-dot layer 7. This region that exhibits a deep potential by which electrons e are confined can be formed because the conduction band minimum (CBM) of the quantum-dot layer 7 is lower than the LUMO of the light-emitting layer 4′ so that the LUMO of the light-emitting layer 4′ produces a high barrier to the electrons e injected from the electron transport layer 5 side to the quantum-dot layer 7.

In addition, the valence band maximum (VBM) of the quantum-dot layer 7 is lower than the HOMO of the light-emitting layer 4′ and produces a high barrier to those holes h in the light-emitting layer 4′ which are injected from the hole transport layer 3 side, so that the holes h in the light-emitting layer 4′ can be confined in the light-emitting layer 4′.

Note that when the quantum-dot layer 7 and the electron transport layer 5 are joined, the band of the quantum-dot layer 7 significantly bends across the thickness direction under the influence of the electron transport layer 5. This is because the concentration of electrons e in the electron transport layer 5 is higher than the concentration of electrons e in the quantum-dot layer 7. The electron transport layer 5, which has a shallow conduction band minimum (CBM) and a pseudo-degenerate Fermi level, produces a high barrier in a limited region on a side near the quantum-dot layer 7. However, this barrier is so thin that electrons e can readily tunnel through the barrier under an application voltage.

The region that is formed in the quantum-dot layer 7 and that exhibits a deep potential by which electrons e are confined contains only electrons e and no holes h as carriers. Therefore, no recombination of electrons e and holes h, hence no emission of light, occurs. Therefore, the quantum-dot layer 7 forms a region that exhibits a deep potential by which electrons e are confined without being lost.

The light-emitting layer 4′ confines the holes h injected from the anode 2 to the light-emitting layer 4′ via the hole transport layer 3 and is fed with overflowing electrons approximately 1/10 the number of electrons e confined in the region that is formed in the quantum-dot layer 7 and that exhibits a deep potential by which electrons e are confined. Therefore, in the light-emitting layer 4′, electrons e and holes h recombine, thereby emitting light.

As described above, in the light-emitting element 1c in accordance with the present embodiment, approximately 1/10 the number of electrons e confined in the region that is formed in the quantum-dot layer 7 and that exhibits a deep potential by which electrons e are confined overflow and are fed to the light-emitting layer 4′. Therefore, in the light-emitting layer 4′, the charge-carrier balance of electrons e and holes his significantly improved, and the resultant light-emitting element 1c exhibits improved luminous efficiency. In addition, since this improvement of the charge-carrier balance significantly reduces the number of electrons e that flow out to the hole transport layer 3 side, the hole transport layer 3 can be restrained from being degraded even if the hole transport layer 3 is made of an organic material. Furthermore, if the hole transport layer 3 is made of an inorganic material, the degradation is further restrained. Therefore, the light-emitting element 1c exhibits improved reliability.

In FIG. 17, (d) is a schematic band diagram for a quantum-dot layer 107 and a light-emitting layer 104 when the quantum-dot layer 107 and the light-emitting layer 104 are not joined, (e) is a schematic band diagram for the quantum-dot layer 107 and the light-emitting layer 104 when the quantum-dot layer 107 and the light-emitting layer 104 are joined, and (f) is a schematic band diagram for the quantum-dot layer 107 and the light-emitting layer 104 when the quantum-dot layer 107 and the light-emitting layer 104 are under an application voltage.

When the conduction band minimum (CBM) of the quantum-dot layer 107 is higher than the LUMO of the light-emitting layer 104, and the valence band maximum (VBM) of the quantum-dot layer 107 is higher than the HOMO of the light-emitting layer 104, as shown in (f) of FIG. 17, no region that exhibits a deep potential by which electrons e are confined may possibly be formed, which could lead to spatial separation of electrons e and holes h in the thickness direction of the light-emitting layer 104 and to a failure to improve luminous efficiency.

In FIG. 17, (g) is a schematic band diagram for the quantum-dot layer 107 and the light-emitting layer 104 when the quantum-dot layer 107 and the light-emitting layer 104 are not joined, (h) is a schematic band diagram for the quantum-dot layer 107 and the light-emitting layer 104 when the quantum-dot layer 107 and the light-emitting layer 104 are joined, and (i) is a schematic band diagram for the quantum-dot layer 107 and the light-emitting layer 104 when the quantum-dot layer 107 and the light-emitting layer 104 are under an application voltage.

When the conduction band minimum (CBM) of the quantum-dot layer 107 is at the same energy level as the LUMO of the light-emitting layer 104, and the valence band maximum (VBM) of the quantum-dot layer 107 is at the same energy level as the HOMO of the light-emitting layer 104, as shown in (i) of FIG. 17, there occurs no shift in energy level, so that no region can be formed that exhibits a deep potential by which electrons e are confined. Therefore, luminous efficiency may possibly not be improved.

The present embodiment has so far discussed an example where the light-emitting layer 4′ is made of an organic material containing no quantum dots (QDs). However, even when the light-emitting layer 4′ contains first quantum dots (QDs), the quantum-dot layer 7 containing second quantum dots (QDs) may be provided separately from the light-emitting layer 4′. When this is the case, the second quantum dots (QDs) contained in the quantum-dot layer 7 and the first quantum dots (QDs) contained in the light-emitting layer 4′ may be the same type of quantum dots or may be different types of quantum dots.

### General Description

### Aspect 1

A light-emitting element including:
a cathode;
an anode opposite the cathode;
a light-emitting layer between the cathode and the anode; and
an electron transport layer between the cathode and the light-emitting layer, the electron transport layer containing either a compound containing a Group IIB (12) element, a Group IVB (14) element, and elemental nitrogen or a compound containing the Group IVB (14) element, a Group VIB (16) element, and elemental boron.

### Aspect 2

The light-emitting element of aspect 1, wherein
the electron transport layer contains the compound containing the Group IIB (12) element, the Group IVB (14) element, and the elemental nitrogen, and
the compound has chemical formula AₓD_{y}N_{z},
where A is the Group IIB (12) element, D is the Group IVB (14) element, N is the elemental nitrogen, x is a numerical value of from 0.75 to 1.25 both inclusive, y is a numerical value of from 0.75 to 1.25 both inclusive, and z is a numerical value of from 1.5 to 2.5 both inclusive.

### Aspect 3

The light-emitting element of aspect 1 or 2, wherein the electron transport layer contains the compound containing the Group IIB (12) element, the Group IVB (14) element, and the elemental nitrogen, and the Group IIB (12) element is Zn.

### Aspect 4

The light-emitting element of aspect 1, wherein
the electron transport layer contains the compound containing the Group IVB (14) element, the Group VIB (16) element, and the elemental boron, and
the compound has chemical formula DₓE_{y}B_{z},
where D is the Group IVB (14) element, E is the Group VIB (16) element, B is the elemental boron, x is a numerical value of from 0.75 to 1.25 both inclusive, y is a numerical value of from 0.75 to 1.25 both inclusive, and z is a numerical value of from 1.5 to 2.5 both inclusive.

### Aspect 5

The light-emitting element of aspect 1 or 4, wherein
the electron transport layer contains the compound containing the Group IVB (14) element, the Group VIB (16) element, and the elemental boron, and
the Group VIB (16) element is one or more species selected from S, Se, and O.

### Aspect 6

The light-emitting element of any one of aspects 1 to 5, wherein the Group IVB (14) element is a species selected from Si, Ge, and Sn.

### Aspect 7

The light-emitting element of any one of aspects 1 to 5, wherein the Group IVB (14) element contains two or more species selected from Si, Ge, and Sn.

### Aspect 8

The light-emitting element of any one of aspects 1 to 7, wherein the electron transport layer is an n-type semiconductor.

### Aspect 9

The light-emitting element of any one of aspects 1 to 8, wherein the electron transport layer is a degenerate semiconductor.

### Aspect 10

The light-emitting element of any one of aspects 1 to 9, wherein the light-emitting layer contains first quantum dots.

### Aspect 11

The light-emitting element of any one of aspects 1 to 9, wherein
the light-emitting layer contains first quantum dots, and
the electron transport layer is in contact with the light-emitting layer.

### Aspect 12

The light-emitting element of any one of aspects 1 to 9, wherein
the light-emitting layer contains first quantum dots,
an insulating layer having a thickness of less than or equal to 5 nm is provided between the electron transport layer and the light-emitting layer,
the electron transport layer is in contact with the insulating layer, and
the insulating layer is in contact with the light-emitting layer.

### Aspect 13

The light-emitting element of any one of aspects 1 to 10, wherein
a quantum-dot layer containing second quantum dots is provided between the electron transport layer and the light-emitting layer,
the electron transport layer is in contact with the quantum-dot layer, and
the quantum-dot layer is in contact with the light-emitting layer.

### Aspect 14

The light-emitting element of any one of aspects 10 to 13, wherein each of the quantum dots has a core and a shell and exhibits a peak emission wavelength in a visible light range.

### Aspect 15

A light-emitting element including:
a cathode;
an anode opposite the cathode;
a light-emitting layer containing quantum dots between the cathode and the anode; and
an electron transport layer in contact with the light-emitting layer between the cathode and the light-emitting layer, the electron transport layer being an n-type semiconductor, an absolute value of a difference of a conduction band minimum of the electron transport layer from a vacuum energy level being smaller than an absolute value of a difference of a conduction band minimum of the light-emitting layer from the vacuum energy level, wherein
the light-emitting layer includes:
   a first layer in contact with the electron transport layer; and
   a second layer in contact with the first layer and separated from the electron transport layer, and
only the second layer in the light-emitting layer emits light.

### Aspect 16

The light-emitting element of aspect 15, wherein the second layer in the light-emitting layer has a thickness less than or equal to half a thickness of the light-emitting layer.

### Aspect 17

A light-emitting element including:
a cathode;
an anode opposite the cathode;
a light-emitting layer between the cathode and the anode; and
an electron transport layer between the cathode and the light-emitting layer, wherein
the electron transport layer has an ionization potential and an electron affinity both of which have a lower value than a value of an electron affinity of the light-emitting layer and also exhibits a band gap.

### Aspect 18

The light-emitting element of aspect 17, wherein the value of the electron affinity of the electron transport layer is lower than or equal to 1 eV.

### Aspect 19

The light-emitting element of aspect 17 or 18, wherein the value of the ionization potential of the electron transport layer is lower than or equal to 2.55 eV.

### Aspect 20

The light-emitting element of any one of aspects 15 to 19, wherein
the light-emitting layer contains quantum dots, and
the quantum dots have a core and a shell and exhibit a peak emission wavelength in a visible light range.

### Aspect 21

The light-emitting element of any one of aspects 17 to 20, wherein the band gap of the electron transport layer has energy with a greater magnitude than a magnitude of energy determined from equation A:

E=hc/λ (equation A) with being equal to 760 nm,
where E is energy (eV), λ is a wavelength (nm), h is Planck's constant, and c is a speed of light.

### Aspect 22

The light-emitting element of aspect 21, wherein the magnitude of the energy of the band gap of the electron transport layer is greater than a magnitude of energy determined from equation A with λ being equal to 450 nm.

### Aspect 23

The light-emitting element of any one of aspects 17 to 22, wherein the light-emitting layer exhibits a band gap that has energy with a magnitude equal to a magnitude of energy determined from equation A:
E=hc/λ (equation A) with λ being equal to a wavelength in a visible light range,
where E is energy (eV), λ is a wavelength (nm), h is Planck's constant, and c is a speed of light.

### Aspect 24

The light-emitting element of aspect 13, wherein the light-emitting layer and the quantum-dot layer have a combined thickness of from 20 nm to 100 nm both inclusive.

### Aspect 25

The light-emitting element of any one of aspects 10 to 12, 15, 16, and 20, wherein the light-emitting layer has a thickness of from 20 nm to 100 nm both inclusive.

### Aspect 26

The light-emitting element of any one of aspects 1 to 25, wherein an absolute value of a difference of a conduction band minimum of the electron transport layer from a vacuum energy level is smaller than 0.3 eV.

### Aspect 27

The light-emitting element of any one of aspects 1 to 3 and 15 to 23, wherein the light-emitting layer exhibits a peak emission wavelength in a red-color range, and the electron transport layer contains ZnSnN₂.

### Aspect 28

The light-emitting element of any one of aspects 1 to 3 and 15 to 23, wherein the light-emitting layer exhibits a peak emission wavelength in a green-color range, and the electron transport layer contains ZnGeN₂.

### Aspect 29

The light-emitting element of any one of aspects 1 to 3 and 15 to 23, wherein the light-emitting layer exhibits a peak emission wavelength in a blue-color range, and the electron transport layer contains ZnSiN₂.

### Aspect 30

The light-emitting element of any one of aspects 1 to 29, wherein either one or both of a hole transport layer and a hole injection layer is/are provided between the anode and the light-emitting layer, and either one or both of the hole transport layer and the hole injection layer contains/contain an inorganic material.

### Aspect 31

The light-emitting element of aspect 30, wherein the hole transport layer containing the inorganic material is provided between the anode and the light-emitting layer, and
the inorganic material is an oxide containing one or more species selected from Zn, Ni, Mg, La, Mo, W, V, and Le.

### Aspect 32

The light-emitting element of aspect 30, wherein
the hole transport layer containing the inorganic material is provided between the anode and the light-emitting layer, and
the inorganic material is either a Group II-VI compound semiconductor or a Group III-V compound semiconductor.

### Aspect 33

The light-emitting element of any one of aspects 1 to 32, wherein
the electron transport layer includes a first electron transport layer and a second electron transport layer, which are provided in a stated order when viewed from a light-emitting layer side, and
the second electron transport layer has an electron affinity that has a lower value than a value of an electron affinity of the first electron transport layer.

### ADDITIONAL REMARKS

The disclosure is not limited to the description of the embodiments above and may be altered within the scope of the claims. Embodiments based on a proper combination of technical means disclosed in different embodiments are encompassed in the technical scope of the disclosure. Furthermore, new technological features can be created by combining different technical means disclosed in the embodiments.

### INDUSTRIAL APPLICABILITY

The disclosure is applicable to, for example, light-emitting elements and display devices and lighting devices including a light-emitting element.

1. A light-emitting element comprising:
a cathode;
an anode opposite the cathode;
a light-emitting layer between the cathode and the anode; and
an electron transport layer between the cathode and the light-emitting layer, the electron transport layer containing either a compound containing a Group IIB (12) element, a Group IVB (14) element, and elemental nitrogen or a compound containing the Group IVB (14) element, a Group VIB (16) element, and elemental boron.

2. The light-emitting element according to claim 1, wherein
the electron transport layer contains the compound containing the Group IIB (12) element, the Group IVB (14) element, and the elemental nitrogen, and
the compound has chemical formula AₓD_{y}N_{z},
where A is the Group IIB (12) element, D is the Group IVB (14) element, N is the elemental nitrogen, x is a numerical value of from 0.75 to 1.25 both inclusive, y is a numerical value of from 0.75 to 1.25 both inclusive, and z is a numerical value of from 1.5 to 2.5 both inclusive.

3. The light-emitting element according to claim 1 or 2, wherein
the electron transport layer contains the compound containing the Group IIB (12) element, the Group IVB (14) element, and the elemental nitrogen, and
the Group IIB (12) element is Zn.

4. The light-emitting element according to claim 1, wherein
the electron transport layer contains the compound containing the Group IVB (14) element, the Group VIB (16) element, and the elemental boron, and
the compound has chemical formula DₓE_{y}B_{z},
where D is the Group IVB (14) element, E is the Group VIB (16) element, B is the elemental boron, x is a numerical value of from 0.75 to 1.25 both inclusive, y is a numerical value of from 0.75 to 1.25 both inclusive, and z is a numerical value of from 1.5 to 2.5 both inclusive.

5. The light-emitting element according to claim 1 or wherein the electron transport layer contains the compound containing the Group IVB (14) element, the Group VIB (16) element, and the elemental boron, and
the Group VIB (16) element is one or more species selected from S, Se, and O.

6. (canceled)

7. (canceled)

8. The light-emitting element according to claim 1, wherein the electron transport layer is an n-type semiconductor.

9. The light-emitting element according to claim 1, wherein the electron transport layer is a degenerate semiconductor.

10. (canceled)

11. The light-emitting element according to claim 1, wherein
the light-emitting layer contains first quantum dots, and
the electron transport layer is in contact with the light-emitting layer.

12. (canceled)

13. The light-emitting element according to claim 1, wherein
a quantum-dot layer containing second quantum dots is provided between the electron transport layer and the light-emitting layer,
the electron transport layer is in contact with the quantum-dot layer, and
the quantum-dot layer is in contact with the light-emitting layer.

14. (canceled)

15. A light-emitting element comprising:
a cathode;
an anode opposite the cathode;
a light-emitting layer containing quantum dots between the cathode and the anode; and
an electron transport layer in contact with the light-emitting layer between the cathode and the light-emitting layer, the electron transport layer being an n-type semiconductor, an absolute value of a difference of a conduction band minimum of the electron transport layer from a vacuum energy level being smaller than an absolute value of a difference of a conduction band minimum of the light-emitting layer from the vacuum energy level, wherein
the light-emitting layer includes:
a first layer in contact with the electron transport layer; and
a second layer in contact with the first layer and separated from the electron transport layer, and
only the second layer in the light-emitting layer emits light.

16. The light-emitting element according to claim 15, wherein the second layer in the light-emitting layer has a thickness less than or equal to half a thickness of the light-emitting layer.

17. A light-emitting element comprising:
a cathode;
an anode opposite the cathode;
a light-emitting layer between the cathode and the anode; and
an electron transport layer between the cathode and the light-emitting layer, wherein
the electron transport layer has an ionization potential and an electron affinity both of which have a lower value than a value of an electron affinity of the light-emitting layer and also exhibits a band gap.

18. The light-emitting element according to claim 17, wherein the value of the electron affinity of the electron transport layer is lower than or equal to 1 eV.

19. The light-emitting element according to claim 17, wherein the value of the ionization potential of the electron transport layer is lower than or equal to 2.55 eV.

20. (canceled)

21. The light-emitting element according to claim 17, wherein the band gap of the electron transport layer has energy with a greater magnitude than a magnitude of energy determined from equation A:
E=hc/λ, (equation A) with λ, being equal to 760 nm,
where E is energy (eV), λ, is a wavelength (nm), h is Planck's constant, and c is a speed of light.

22. The light-emitting element according to claim 21, wherein the magnitude of the energy of the band gap of the electron transport layer is greater than a magnitude of energy determined from equation A with being equal to 450 nm.

23. The light-emitting element according to claim 17, wherein the light-emitting layer exhibits a band gap that has energy with a magnitude equal to a magnitude of energy determined from equation A:
E=hc/λ (equation A) with λ being equal to a wavelength in a visible light range,
where E is energy (eV), λ is a wavelength (nm), h is Planck's constant, and c is a speed of light.

24. The light-emitting element according to claim 13, wherein the light-emitting layer and the quantum-dot layer have a combined thickness of from 20 nm to 100 nm both inclusive.

25. The light-emitting element according to claim 15, wherein the light-emitting layer has a thickness of from 20 nm to 100 nm both inclusive.

26-32. (canceled)

33. The light-emitting element according to claim 1, wherein
the electron transport layer includes a first electron transport layer and a second electron transport layer, which are provided in a stated order when viewed from a light-emitting layer side, and
the second electron transport layer has an electron affinity that has a lower value than a value of an electron affinity of the first electron transport layer.
